(19) United States
(12) Patent Application Publication
(10) Pub. No.: US 2024/0418948 A1
(43) Pub. Date: Dec. 19, 2024

(54) OPTICAL MODULE

(71) Applicant: HISENSE BROADBAND MULTIMEDIA TECHNOLOGIES CO., LTD., Qingdao (CN)

(72) Inventors: Yongjun YU, Qingdao (CN); Pengfei LIU, Qingdao (CN); Dengshan XUE, Qingdao (CN); Qisheng ZHAO, Qingdao (CN); Xiaokuo ZHANG, Qingdao (CN); Jianwei MU, Qingdao (CN)

(21) Appl. No.: 18/755,939

(22) Filed: Jun. 27, 2024

Related U.S. Application Data
(63) Continuation of application No. PCT/CN2023/121490, filed on Sep. 26, 2023.

(30) Foreign Application Priority Data
Mar. 31, 2023 (CN) 202310339617.5
Mar. 31, 2023 (CN) 202310341937.4
Mar. 31, 2023 (CN) 202310344262.9
Mar. 31, 2023 (CN) 202310344269.0
Aug. 28, 2023 (CN) 202311090731.5
Aug. 28, 2023 (CN) 202311090738.7
Aug. 28, 2023 (CN) 202311094008.4
Aug. 28, 2023 (CN) 202311094022.4

(51) Int. Cl. G02B 6/42; G02B 6/293; H01S 5/024

(52) U.S. Cl. CPC G02B 6/4215; G02B 6/29386; G02B 6/4214; H01S 5/02415

(57) ABSTRACT

In an optical module, one end of an optical fiber adapter is configured to connect with an external optical fiber; an optical accommodation component is connected to the other end of the optical fiber adapter; a light emission component is configured to emit emission optical signals including a first-wavelength optical signal, a second-wavelength optical signal and a third-wavelength optical signal to the optical accommodation component, the emission optical signals are then transmitted to the external optical fiber via the optical fiber adapter; the optical accommodation component includes a first cavity member and an optical assembly disposed in the first cavity member, the first cavity member is connected, at one end thereof, to the optical fiber adapter and, at the other end thereof, to the light emission component, and one side of the first cavity member is provided with three light reception components at intervals.

### CROSS-REFERENCE TO RELATED APPLICATIONS

This application is a continuation application of PCT/CN2023/121490 filed on Sep. 26, 2023, which claims priority to Chinese patent application numbers: 202310339617.5 filed with the China National Intellectual Property Administration (CNIPA) on Mar. 31, 2023; 202310341937.4 filed with the CNIPA on Mar. 31, 2023; 202310344269.0 filed with the CNIPA on Mar. 31, 2023; 202310344262.9 filed with the CNIPA on Mar. 31, 2023; 202311090731.5 filed with the CNIPA on Aug. 28, 2023; 202311094008.4 filed with the CNIPA on Aug. 28, 2023; 202311094022.4 filed with the CNIPA on Aug. 28, 2023; and 202311090738.7 filed with the CNIPA on Aug. 28, 2023; all of which are incorporated into the present application by reference in their entirety.

### FIELD

The present disclosure relates to the field of optical communication technologies, and in particular to an optical module.

### BACKGROUND

With the development of cloud computing, mobile Internet, video and other new services and application models, the development and progress of optical communication technology has become increasingly important. In optical communication technology, optical module is a tool for achieving mutual conversion of optical and electric signals and is one of the key components in optical communication equipment. Also, with the development of optical communication technology, the transmission rate of optical module continues to increase. In some optical modules, optical modules with high transmission rate have higher integration density than optical modules with low transmission rate, for example, multi-channel optical receiving and transmitting technology is employed so as to achieve transmission and reception of multi-wavelength optical signals in optical modules.

### SUMMARY

The present disclosure provides an optical module, including an optical fiber adapter, an optical accommodation component and a light emission component. One end of the optical fiber adapter is configured to connect with an external optical fiber. The optical accommodation component is connected to the other end of the optical fiber adapter, so as to receive reception optical signals including a fourth-wavelength optical signal, a fifth-wavelength optical signal and a sixth-wavelength optical signal via the optical fiber adapter. The light emission component is configured to emit emission optical signals including a first-wavelength optical signal, a second-wavelength optical signal and a third-wavelength optical signal. The optical accommodation component includes a first cavity member, an optical assembly, a first light reception component, a second light reception component and a third light reception component. One end of the first cavity member is connected to the optical fiber adapter, and the other end of the first cavity member is connected to the light emission component. The first light reception component, the second light reception component, and the third light reception component are provided at one side of the first cavity member at intervals. The optical assembly includes: a first displacement prism, with a first reflective surface of the first displacement prism located in an optical path of the optical fiber adapter; a first filter located in an optical path of the light emission component and in a reflective optical path of a second reflective surface of the first displacement prism; wherein the emission optical signals are transmitted to the first displacement prism through the first filter, and then transmitted to the optical fiber adapter via the second and first reflective surfaces of the first displacement prism, and the optical fiber adapter is configured to transmit the reception optical signals to the first filter via the first and second reflective surfaces of the first displacement prism; a reflector located in a reflection light path of the first filter, to receive the reception optical signals reflected by the first filter; a first wavelength division multiplexer located in a reflection light path of the reflector and configured to split the reception optical signals reflected by the reflector into the fourth-wavelength optical signal, the fifth-wavelength optical signal and the sixth-wavelength optical signal according to wavelength, wherein the first light reception component, the second light reception component and the third light reception component are all located in an output optical path of the first-wavelength division multiplexer, and the first light reception component is configured to receive the fourth-wavelength light signal, the second light reception component is configured to receive the fifth-wavelength light signal, and the third light reception component is configured to receive the sixth-wavelength light signal.

### DRAWINGS

To more clearly describe the technical solutions of the present disclosure, the accompanying drawings to be used in some embodiments of the present disclosure will be described briefly below. The accompanying drawings, as described below, are only those of some embodiments of the present disclosure, and for those skilled in the art, other drawings may also be derived from these accompanying drawings. In addition, the accompanying drawings as described below may be regarded as schematic diagrams and are not intended to limit the actual size of the product, the actual process of the method, or the actual timing of the signal involved in the disclosed embodiments.

FIG. 1 is a partial architecture diagram of an optical communication system provided according to some embodiments of the present disclosure;

FIG. 2 is a partial structural diagram of a master computer provided according to some embodiments of the present disclosure;

FIG. 3 is a structural schematic diagram of an optical module provided according to some embodiments of the present disclosure;

FIG. 4 is an exploded diagram of an optical module provided according to some embodiments of the present disclosure;

FIG. 5 is a schematic diagram showing an internal structure of an optical module provided according to some embodiments of the present disclosure;

FIG. 6 is an exploded schematic diagram showing an internal structure of an optical module provided according to some embodiments of the present disclosure;

FIG. 7 is a schematic diagram showing an assembly of an optical fiber adapter and a first cavity member provided according to some embodiments of the present disclosure;

FIG. 8 is an exploded schematic diagram of an optical fiber adapter and a first cavity member provided according to some embodiments of the present disclosure;

FIG. 9 is a sectional diagram of an optical fiber adapter and a first cavity member provided according to some embodiments of the present disclosure;

FIG. 10 is an exploded schematic diagram of a first cavity member provided according to some embodiments of the present disclosure;

FIG. 11 is a first structural schematic diagram of a first housing provided according to some embodiments of the present disclosure;

FIG. 12 is a second structural schematic diagram of a first housing provided according to some embodiments of the present disclosure;

FIG. 13 is a third structural schematic diagram of a first housing provided according to some embodiments of the present disclosure;

FIG. 14 is a fourth structural schematic diagram of a first housing provided according to some embodiments of the present disclosure;

FIG. 15 is a first sectional diagram of a first housing provided according to some embodiments of the present disclosure;

FIG. 16 is a second sectional diagram of a first housing provided according to some embodiments of the present disclosure;

FIG. 17 is a diagram of a first housing provided according to some embodiments of the present disclosure in a usage state;

FIG. 18 is a sectional diagram of a first housing provided according to some embodiments of the present disclosure in a usage state;

FIG. 19 is a diagram of a reflector bracket provided according to some embodiments of the present disclosure in a usage state;

FIG. 20 is a diagram of an optical assembly provided according to some embodiments of the present disclosure in an assembly state;

FIG. 21 is a sectional diagram of a light reception component and a first housing provided according to some embodiments of the present disclosure in an assembly state;

FIG. 22 is an exploded schematic diagram of a first housing and a light emission component provided according to some embodiments of the present disclosure;

FIG. 23 is a first exploded schematic diagram of a light emission component provided according to some embodiments of the present disclosure;

FIG. 24 is a diagram of a light emission component and a first housing provided according to some embodiments of the present disclosure in a connection state;

FIG. 25 is a second exploded schematic diagram of a light emission component provided according to some embodiments of the present disclosure;

FIG. 26 is a first partial structural schematic diagram of a light emission component provided according to some embodiments of the present disclosure;

FIG. 27 is a second partial structural schematic diagram of a light emission component provided according to some embodiments of the present disclosure;

FIG. 28 is a partially exploded schematic diagram of a light emission component provided according to some embodiments of the present disclosure;

FIG. 29 is a structural schematic diagram of a first circuit board provided according to some embodiments of the present disclosure;

FIG. 30 is a partially enlarged diagram of area M of the light emission component in FIG. 27;

FIG. 31 is a partially enlarged diagram of area N of the light emission component in FIG. 27;

FIG. 32 is a first structural schematic diagram of a support plate provided according to some embodiments of the present disclosure;

FIG. 33 is a second structural schematic diagram of a support plate provided according to some embodiments of the present disclosure;

FIG. 34 is a diagram of a support plate provided according to some embodiments of the present disclosure in a usage state;

FIG. 35 is a first structural schematic diagram of a second housing provided according to some embodiments of the present disclosure;

FIG. 36 is a second structural schematic diagram of a second housing provided according to some embodiments of the present disclosure;

FIG. 37 is a diagram illustrating an optical path of a transmitted optical signal according to some embodiments of the present disclosure;

FIG. 38 is a first exploded schematic diagram illustrating an internal structure of an optical module provided according to some embodiments of the present disclosure;

FIG. 39 is a second exploded schematic diagram illustrating an internal structure of an optical module provided according to some embodiments of the present disclosure;

FIG. 40 is a structural schematic diagram of a first flexible circuit board provided according to some embodiments of the present disclosure;

FIG. 41 is a structural schematic diagram of a second flexible circuit board provided according to some embodiments of the present disclosure;

FIG. 42 is a structural schematic diagram of a third flexible circuit board provided according to some embodiments of the present disclosure;

FIG. 43 is a first schematic diagram illustrating a partial structure of an optical module provided according to some embodiments of the present disclosure;

FIG. 44 is a second schematic diagram illustrating a partial structure of an optical module provided according to some embodiments of the present disclosure;

FIG. 45 is a first diagram of a circuit board provided according to some embodiments of the present disclosure in a usage state;

FIG. 46 is a second diagram of a circuit board provided according to some embodiments of the present disclosure in a usage state;

FIG. 47 is a diagram illustrating a pin definition of a gold finger according to some embodiments of the present disclosure;

FIG. 48 is a third diagram of a circuit board provided according to some embodiments of the present disclosure in a usage state;

FIG. 49 is a fourth diagram of a circuit board provided according to some embodiments of the present disclosure in a usage state;

FIG. 50 shows a high-frequency signal transmission circuit structure of a second driver provided according to some embodiments of the present disclosure;

FIG. 51 is a circuit schematic diagram provided according to some embodiments of the present disclosure;

FIG. 52 is a first schematic diagram illustrating a partial structure a of a circuit board provided according to some embodiments of the present disclosure; and

FIG. 53 is a second schematic diagram illustrating a partial structure of a circuit board provided according to some embodiments of the present disclosure.

### DETAILED DESCRIPTION

Technical solutions of some embodiments of this disclosure will be described clearly and in detail with reference to the accompanying drawings below. Obviously, these embodiments are merely some, but not all, of the embodiments of this disclosure. All other embodiments obtained by those skilled in the art based on the embodiments of this disclosure fall within the protection scope of this disclosure.

Optical communication technology establishes information transmission between information processing devices. In the optical communication technology, information is load onto light, and transmission of the information is achieved through propagation of light. The light loaded with information is an optical signal. The optical signal is propagated in the information transmission device, which can reduce loss of optical power and achieve high-speed, long-distance, and low-cost information transmission. The information that can be processed by the information processing device exists in a form of electrical signal. Optical network terminals/gateways, routers, switches, mobile phones, computers, servers, tablets, and televisions are common information processing devices, while optical fibers and waveguides are common information transmission devices.

Conversion of optical and electrical signals between the information processing device and the information transmission device is achieved through an optical module. For example, the optical module is connected, at an optical signal input terminal and/or an optical signal output terminal thereof, with an optical fiber, and is connected, at an electrical signal input and/or an electrical signal output terminal thereof, with an optical network terminal; a first optical signal from the optical fiber is transmitted into the optical module, which converts the first optical signal into a first electrical signal, and then transmits the first electrical signal to the optical network terminal; and a second electrical signal from the optical network terminal is transmitted into the optical module, which converts the second electrical signal into a second optical signal, and then transmits the second optical signal into the optical fiber. Since the information processing devices may be connected to each other via an electrical signal network, at least one type of information processing device needs to be directly connected to the optical module, and it is unnecessary for all types of information processing device to be directly connected to the optical module. The information processing device directly connected to the optical module is called as a master computer of the optical module.

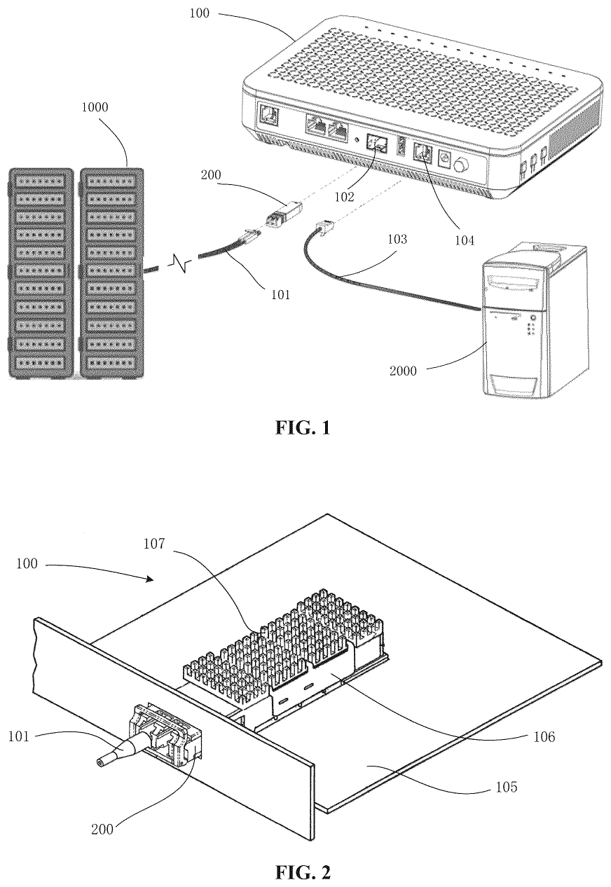

FIG. 1 is a partial architecture diagram of an optical communication system provided according to some embodiments of this disclosure. As shown in FIG. 1, the optical communication system is partially presented as a remote information processing device 1000, a local information processing device 2000, a master computer 100, an optical module 200, an optical fiber 101, and a network cable 103.

One end of the optical fiber 101 extends towards the remote information processing device 1000, and the other end of the optical fiber is coupled to an optical interface of the optical module 200. An optical signal may undergo a total reflection in the optical fiber 101, and propagation of the optical signal in a total reflection direction can almost maintain an original optical power. The optical signal undergoes multiple total reflections in the optical fiber 101, such that the optical signal from the remote information processing device 1000 is transmitted into the optical module 200, or the light from the optical module 200 is propagated towards the remote information processing device 1000, thereby achieving long-distance and low-power-loss information transmission.

There may be one optical fiber 101 or a plurality (two or more) of optical fibers 101. The optical fiber(s) 101 may be connected to the optical module 200 in a pluggable manner or in a fixed connection manner.

The master computer 100 has an optical module interface 102, which is configured to be coupled to the optical module 200, thereby establishing a unidirectional/bidirectional electrical signal connection between the master computer 100 and the optical module 200. The master computer 100 is configured to provide data signals to the optical module 200, receive data signals from the optical module 200, or monitor and control working status of the optical module 200.

The master computer 100 has an external electrical interface, such as an Universal Serial Bus (USB) or a network cable interface 104, which may be coupled to the electrical signal network. For example, the network cable interface 104 is configured to be coupled to a network cable 103, thereby establishing a unidirectional/bidirectional electrical signal connection between the master computer 100 and the network cable 103.

Optical Network Unit (ONU), Optical Line Terminal (OLT), Optical Network Terminal (ONT), and Data Center Server are common master computers. One end of the network cable 103 is connected to the local information processing device 2000, and the other end of the network cable is connected to the master computer 100. The network cable 103 establishes an electrical signal connection between the local information processing device 2000 and the master computer 100.

For example, a third electrical signal emitted by the local information processing device 2000 is transmitted to the master computer 100 through the network cable 103. The master computer 100 generates a second electrical signal based on the third electrical signal, and the second electrical signal from the master computer 100 is transmitted to the optical module 200. The optical module 200 converts the second electrical signal into a second optical signal, and transmits the second optical signal to the optical fiber 101. The second optical signal is transmitted to the remote information processing device 1000 through the optical fiber 101.

For example, a first optical signal from the remote information processing device 1000 propagates through the optical fiber 101. The first optical signal propagated through the optical fiber 101 is transmitted into the optical module 200. The optical module 200 converts the first optical signal into a first electrical signal, and transmits the first electrical signal to the master computer 100. The master computer 100 generates a fourth electrical signal based on the first electrical signal, and transmits the fourth electrical signal to the local information processing device 2000.

The optical module is a tool for achieving the conversion between optical and electrical signals. During the conversion between optical and electrical signals as described above, no change is made to the information, but methods for encoding and decoding the information may be changed.

FIG. 2 is a partial structural diagram of a master computer according to some embodiments of this disclosure. In order to clearly illustrate connection relationship between the optical module 200 and the master computer 100, FIG. 2 only shows a structure of the master computer 100 related to the optical module 200. As shown in FIG. 2, the master computer 100 further includes a PCB circuit board 105 disposed within a shell, a cage 106 disposed on a surface of the PCB circuit board 105, a radiator 107 disposed on the cage 106, and an electrical connector (not shown in the Figure) disposed inside the cage 106. The radiator 107 has a raised structure for increasing a heat dissipation area. A fin structure is a common raised structure.

The optical module 200 is inserted into the cage 106 of the master computer 100 and then is secured by the cage 106. Thus, heat generated by the optical module 200 is conducted to the cage 106, and then dissipated via the radiator 107. After the optical module 200 is inserted into the cage 106, an electrical interface of the optical module 200 is connected to the electrical connector inside the cage 106.

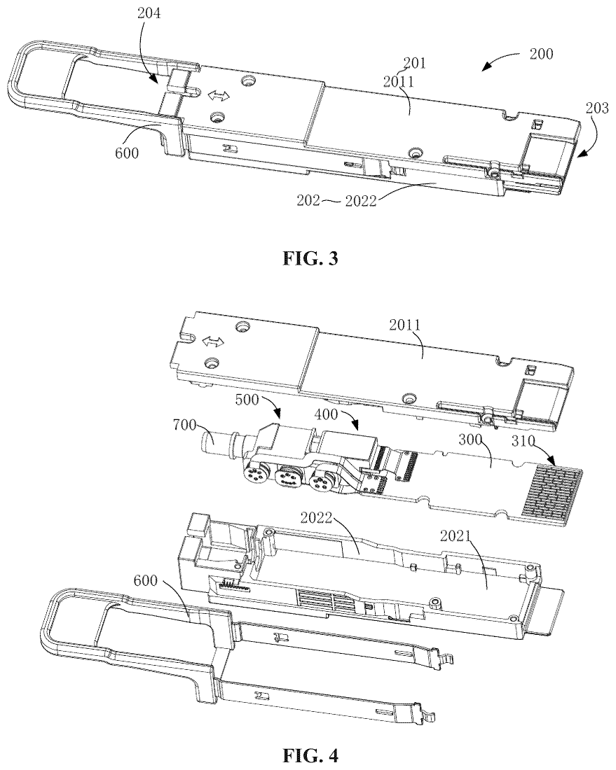

FIG. 3 is a structural diagram of an optical module provided according to some embodiments of this disclosure, and FIG. 4 is an exploded schematic diagram of an optical module provided according to some embodiments of this disclosure. As shown in FIGS. 3 and 4, the optical module 200 includes a shell, within which a circuit board 300, a light emission component 400 and an optical accommodation component 500 are disposed. At least one light reception component is disposed on the optical accommodation 500.

The shell may include an upper shell part 201 and a lower shell part 202. The upper shell part 201 is covered on the lower shell part 202 to form the aforementioned shell having two openings. An outer contour of the shell is generally in a cuboid shape.

In some embodiments, the lower shell part 202 includes a bottom plate 2021 and two lower side plates 2022 located at opposite sides of the bottom plate 2021 and disposed perpendicular to the bottom plate 2021; and the upper shell part 201 includes a cover plate 2011. The cover plate 2011 is covered on the two lower side plates 2022 of the low shell part 202 so as to form the above-mentioned shell.

In some embodiments, the lower shell part 202 includes a bottom plate 2021 and two lower side plates located on opposite sides of the bottom plate 2021 and disposed perpendicular to the bottom plate 2021; and the upper shell part 201 includes a cover plate 2011 and two upper side plates located on opposite sides of the cover plate 2011 and disposed perpendicular to the cover plate 2011; and the two upper side plates combine with the two lower side plates to achieve the covering of the upper shell part 201 on the lower shell part 202.

A direction along a connecting line between the two openings 203 and 204 may be consistent with a length direction of the optical module 200 or inconsistent with the length direction of the optical module 200. For example, the opening 203 is located at an end of the optical module 200 (right end in FIG. 3), and the opening 204 is also located at an end of the optical module 200 (left end in FIG. 3). Alternatively, the opening 203 is located at an end of the optical module 200, while the opening 204 is located at a side of the optical module 200. The opening 203 is an electrical port and a golden finger of the circuit board 300 extends from the electrical port and is inserted into the master computer (e.g., the Optical Network Terminal 100). The opening 204 is an optical port configured to be coupled to the optical fiber 101 such that the optical fiber 101 is connected with the light emission component 400 and/or the optical accommodation component 500 in the optical module 200.

The assembling way in which the upper shell part 201 is combined with the lower shell part 202 facilitates mounting the circuit board 300, the light emission component 400, the optical accommodation component 500 and the like into the shell, such that these components may be encapsulated and protected by the upper shell part 201 and the lower shell part 202. In addition, when assembling the circuit board 300, the light emission component 400, the optical accommodation component 500 and the like, this assembling way facilitates deploying positioning elements, heat dissipation elements, and electromagnetic shielding elements, which is conducive to automated production implementation. In some embodiments, the upper shell part 201 and lower shell part 202 are generally made of metal materials, which facilitates achieving electromagnetic shielding and heat dissipation.

In some embodiments, the optical module 200 further includes an unlocking component 600 located outside the shell of the optical module. The unlocking component 600 is configured to achieve a fixed connection between the optical module 200 and the master computer or release the optical module 200 from the master computer.

For example, the unlocking component 600 is located at an end of the lower shell part 202, and includes a snap-fitting part matching with the cage of the master computer (e.g., the cage 106 of the Optical Network Terminal 100). When the optical module 200 is inserted into the cage of the master computer, the snap-fitting part of the unlocking component 600 secures the optical module 200 within the cage of the master computer. As the unlocking component 600 is pulled, the unlocking component 600 rotates and the snap-fitting part of the unlocking component 600 moves accordingly, and thus the connection relationship between the snap-fitting part and the master computer is changed, thereby releasing the snap-fitting connection between the optical module 200 and the master computer, such that the optical module 200 can be drawn out from the cage of the master computer. In some embodiments, the unlocking component 600 is located on outer walls of the two lower side plates 2022 of the lower shell part 202, and includes a snap-fitting part that matches with the master computer (e.g., the cage 106 of the Optical Network Terminal 100).

The circuit board 300 includes circuit wiring, electronic elements, chips, and so on. The electronic elements and the chips are connected through the circuit wiring according to a circuit design so as to achieve various functions such as power supply, electrical signal transmission, and grounding. For example, the electronic elements may include capacitors, resistors, transistors, and Metal-Oxide-Semiconductor Field-Effect Transistors (MOSFETs). For example, the chips may include microcontroller units (MCUs), laser driver chips, limiting amplifiers (LAs), clock and data recovery (CDR) chips, power management chips, and digital signal processing (DSP) chips.

The circuit board 300 further includes a gold finger formed on a surface of an end thereof, which is composed of a plurality of pins independent from each other. The circuit board 300 is inserted into the cage 106 and is conductively connected to the electrical connector inside the cage 106 via the golden finger. The golden finger may be disposed only on one surface of the circuit board 300 (e.g., an upper surface shown in FIG. 4), or on both upper and lower surfaces of the circuit board 300 to be suitable to applications where a larger number of pins are required. The golden finger is configured to establish an electrical connection with the master computer to achieve power supply, grounding, Inter-Integrated Circuit (I2C) signal transmission, data signal transmission or the like.

In some embodiments, the light emission component 400 is configured to achieve emission of optical signals, and the light reception component of the optical accommodation component 500 is configured to achieve reception of optical signals. For example, the optical accommodation component 500 is configured to realize combination of the light emission component 400 and the light reception component so as to form an integrated optical transceiver component with a shared optical fiber adapter. Of course, in some embodiments of the present application, the light emission component and the optical accommodation component may also be separated from each other, that is, the light emission component and the optical accommodation component do not share the shell.

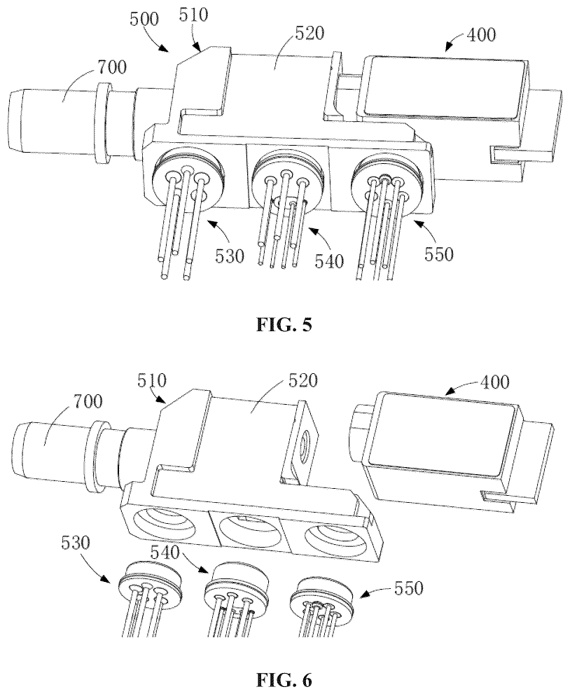

FIG. 5 is a schematic diagram illustrating an internal structure of an optical module provided according to some embodiments of the present disclosure, and FIG. 6 is an exploded schematic diagram of an internal structure of an optical module provided according to some embodiments of the present disclosure. As shown in FIGS. 5 and 6, one end of the optical accommodation component 500 is connected with an optical fiber adapter 700, and the other end of the optical accommodation component 500 is connected with the light emission component 400. An optical signal generated by the light emission component 400 is transmitted to the optical accommodation component 500, then transmitted to the optical fiber adapter 700 through the optical accommodation component 500, and finally output through the optical fiber adapter 700. An externally input optical signal is transmitted to the optical accommodation component 500 through the optical fiber adapter 700. Thus, the optical accommodation component 500 and the light emission component 400 share the optical fiber adapter 700, such that uplink and downlink optical signals of the optical module share an optical fiber 101.

In some embodiments, the light emission component 400 may generate optical signals of multiple wavelengths, and these optical signals of multiple wavelengths are combined into one beam of optical signals. A plurality of light reception components are disposed on the optical accommodation component 500 such that the optical accommodation component 500 can receive optical signals of multiple wavelengths. For example, the light emission component 400 generates optical signals of three wavelengths, and the optical accommodation component 500 receives optical signals of three wavelengths.

As shown in FIGS. 5 and 6, in some embodiments, the optical accommodation component 500 includes a first cavity member formed by covering a first upper cover 520 on a first housing 510, and includes a first light reception component 530, a second light reception component 540 and a third light reception component 550. The first cavity member is provided therein with an accommodation cavity which is configured to accommodate devices and achieve connections or communications with other devices. In some embodiments, the first housing 510 is provided therein with an inner cavity, so as to form the accommodation cavity upon covering the first upper cover 520 on the first housing 510.

In some embodiments, the first housing 510 is connected with the light emission component 400, the first light reception component 530, the second light reception component 540 and the third light reception component 550, so as to achieve package of the light emission component 400, the first light reception component 530, the second light reception component 540 and the third light reception component 550 by means of the first housing 510, as well as achieve light coupling of the light emission component 400, the first light reception component 530, the second light reception component 540, and the third light reception component 550 with the inside of the first cavity member, respectively.

In some embodiments, the optical module 200 is configured to receive a beam of optical signals including three wavelengths and to emit a beam of optical signals including three wavelengths. For example, the light emission component 400 may output a beam of optical signals including a first wavelength, a second wavelength, and a third wavelength, the first light reception component 530 may receive an optical signal having a fourth wavelength, the second light reception component 540 may receive an optical signal having a fifth wavelength, and the third light reception component 550 may receive an optical signal having a sixth wavelength.

In some embodiments, the light emission component 400 is packaged in a micro-optics packaging manner, and the first light reception component 530, the second light reception component 540, and the third light reception component 550 are packaged in a coaxial packaging manner. For example, optical axes of the first light reception component 530, the second light reception component 540 and the third light reception component 550 are parallel to each other. In some embodiments, the light emission component 400, the first light reception component 530, the second light reception component 540 and the third light reception component 550 are respectively electrically connected to the circuit board 300 through a flexible circuit board.

In some embodiments, the optical fiber adapter 700 is connected to a first side of the first housing 510, the first light reception component 530, the second light reception component 540 and the third light reception component 550 are disposed on a second side of the first housing 510, and the light emission component 400 is disposed on a third side of the first housing 510. For example, the first side of the first housing 510 is close to the optical port of the optical module, the second side of the first housing 510 is close to the lower side plate 2022 of the lower shell part 202, and the third side of the first housing 510 is close to the electrical port of the optical module.

In some embodiments, a fourth connection hole is provided in the first side of the first housing 510, a first connection hole, a second connection hole and a third connection hole are provided in the second side of the first housing 510, and a fifth connection hole is provided in the third side of the first housing 510. The first connection hole, the second connection hole, the third connection hole, the fourth connection hole, and the fifth connection hole are respectively connected to the inner cavity of the first housing 510. The other end of the optical fiber adapter 700 is connected to the fourth connection hole, the first light reception component 530 is connected to the first connection hole, the second light reception component 540 is connected to the second connection hole, the third light reception component 550 is connected to the third connection hole, and the light emission component 400 is connected to the fifth connection hole. For example, the first connection hole, the second connection hole and the third connection hole are arranged sequentially in the second side of the first housing 510.

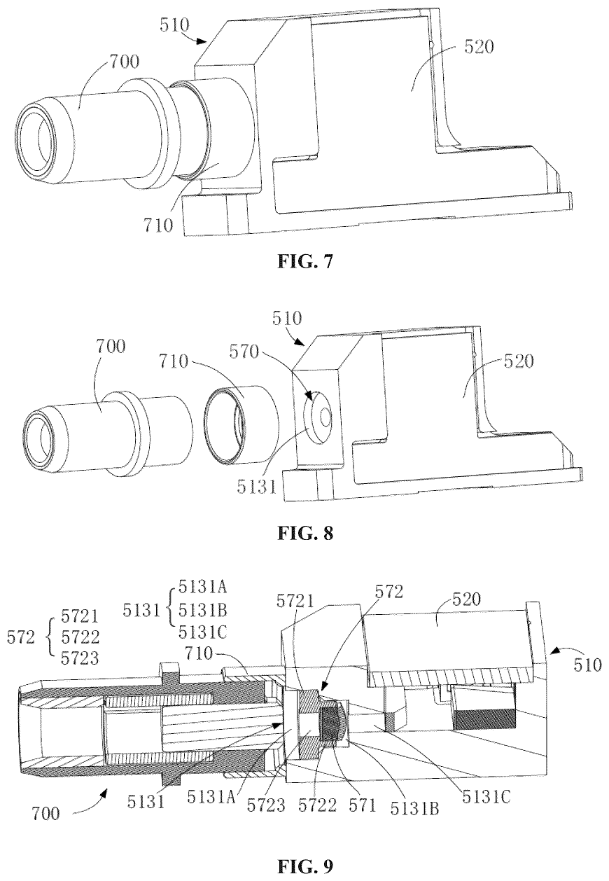

FIG. 7 is a schematic diagram illustrating an assembly of an optical fiber adapter and a first cavity member provided according to some embodiments of the present disclosure, FIG. 8 is an exploded schematic diagram of an optical fiber adapter and a first cavity member provided according to some embodiments of the present disclosure, and FIG. 9 is a sectional diagram of an optical fiber adapter and a first cavity member provided according to some embodiments of the present disclosure. As shown in FIGS. 7-9, the optical fiber adapter 700 is arranged at one side of the first housing 510, one end of the optical fiber adapter 700 is connected with the optical fiber 101, and the other end of the optical fiber adapter 700 is connected to the first housing 510, such that the first housing 510 is connected to the optical fiber 101 via the optical fiber adapter 700. For example, a fourth connection hole 5131 is provided in one side of the first housing 510, and a connection sleeve 710 is provided on the other end of the optical fiber adapter 700. One end of the connection sleeve 710 is connected with the optical fiber adapter 700, and the other end of the connection sleeve 710 is connected to the first housing 510, such that the optical fiber adapter 700 is communicated with the fourth connection hole 5131. By use of the connection sleeve 710, it is convenient for the optical fiber adapter 700 to be connected to the first housing 510. For example, the other end of the optical fiber adapter 700 is embedded into the connection sleeve 710, and an end of an optical fiber of the optical fiber adapter 700 is located inside the connection sleeve 710.

In some embodiments, a lens assembly 570 is disposed in the fourth connection hole 5131 and is configured to collimate/converge the optical signal. For example, an optical signal transmitted from the first housing 510 to the optical fiber adapter 700 is converged by the lens assembly 570, and an optical signal transmitted from the optical fiber adapter 700 to the first housing 510 is collimated by the lens assembly 570. The arrangement of the lens assembly 570 in the fourth connection hole 5131 facilitates saving space occupied by arranging the lens assembly 570 inside the first housing 510, thereby helping to reduce a volume of the optical accommodation component 500 and making it easier for the optical accommodation component 500 to adapt to an internal space of the optical module 200.

In some embodiments, the lens assembly 570 includes a lens 571 and a lens bracket 572. The lens 571 is disposed on the lens bracket 572, and the lens bracket 572 is assembled and connected to the fourth connection hole 5131, such that the lens 571 is conveniently assembled to the fourth connection hole 5131 via the lens bracket 572. For example, the lens bracket 572 is provided therein with a through hole in an axial direction of the fourth connection hole 5131, and the through hole penetrates through the lens bracket 572, so as to allow optical signals to be transmitted through the through hole and the lens 571. The optical signal transmitted from the first housing 510 to the optical fiber adapter 700 is transmitted through the lens 571 and the through hole to the optical fiber adapter 700. The optical signal transmitted from the optical fiber adapter 700 to the first housing 510 is transmitted through the through hole and through the lens 571 to the inner cavity of the first housing 510. In some embodiments, an optical axis of the lens 571 is parallel to an optical axis of the fiber adapter 700, e.g., in the same straight line.

In some embodiments, the fourth connection hole 5131 is a stepped through hole, that is, it has different diameters at different positions in a length direction of the fourth connection hole 5131. In this way, not only the connection between the first housing 510 and the optical fiber adapter 700 can be achieved, but also optical devices can be conveniently arranged in the first connection hole 5131, and a size at a position where the fourth connection hole 5131 communicates with the accommodation cavity 511 can be conveniently controlled, so as to facilitate adaptation to optical devices arranged in the accommodation cavity 511. For example, the lens bracket 572 includes a bracket fixing portion 5721, a lens fixing portion 5722 and a third through hole 5723 penetrating through the bracket fixing portion 5721 and the lens fixing portion 5722 in an optical axis direction of the lens 571. The bracket fixing portion 5721 is connected to a side wall of the fourth connection hole 5131, and the lens 571 is disposed on the lens fixing portion 5722. In some embodiments, the optical axis of the lens 571 is parallel to a central axis of the third through hole 5723, e.g., they are in the same straight line.

For example, the fourth connection hole 5131 includes a front hole 5131A, a middle hole 5131B and a rear hole 5131C that are sequentially communicated with each other and have different inner diameters, with the rear hole 5131C communicated with the inner cavity of the first housing 510. The bracket fixing portion 5721 is connected to a side wall of the front hole 5131A, the lens 571 is located in the middle hole 5131B, and the optical axis of the lens 571 is in the same straight line as a central axis of the rear hole 5131C.

The inner cavity of the first housing 510 is also configured to dispose an optical assembly including one or more reflectors, one or more filter or other optical devices. The optical assembly is provided to change a transmission optical path of an optical signal entering the first housing 510. For example, the optical signal from outside of the optical module is transmitted into the first housing 510 through the optical fiber adapter 700, and then respectively transmitted to the first light reception component 530, the second light reception component 540 or the third light reception component 550 through the optical assembly arranged in the first housing 510. Optical signal generated by the light emission component 400 is transmitted into the first housing 510, and then transmitted to the optical fiber adapter 700 through the optical assembly in the first housing 510, and then transmitted to the optical fiber through the optical fiber adapter 700.

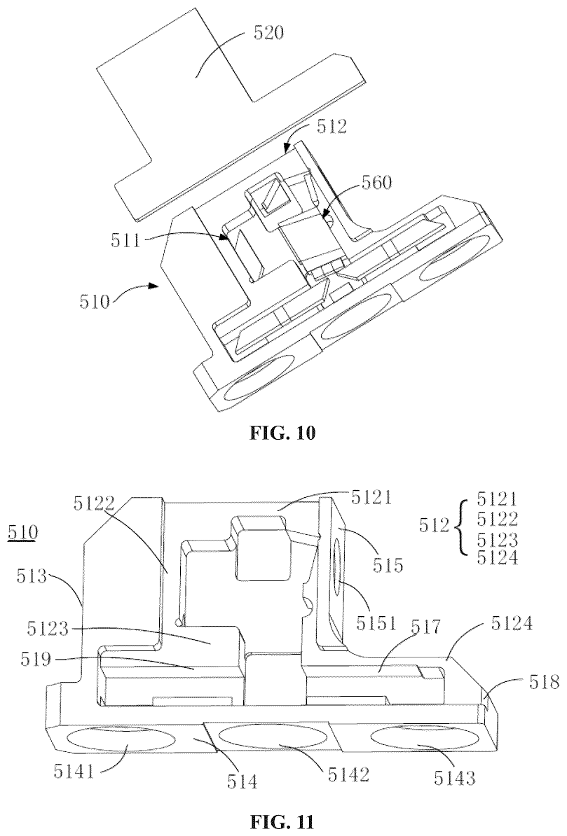

FIG. 10 is an exploded schematic diagram of a first cavity member provided according to some embodiments of the present disclosure. As shown in FIG. 10, the first cavity member includes the first housing 510 and the first upper cover 520. The first upper cover 520 is covered on and connected to the first housing 510, forming a relatively sealed cavity structure through the first upper cover 520 and the first housing 510.

The accommodation cavity 511 is formed in the first housing 510, and the first connection hole, the second connection hole, the third connection hole, the fourth connection hole and the fifth connection hole are respectively provided in the first housing 510 and communicated with the accommodation cavity 511. The accommodation cavity 511 is provided therein with an optical assembly 560 including a first displacement prism, a reflector, a second displacement prism, a third displacement prism, and the like. The first displacement prism, the reflector, the second displacement prism, and the third displacement prism, and the like, are combined to change the transmission optical paths of the optical signals.

In some embodiments, the first housing 510 is provided thereon with a mounting surface 512, which is located lower than a top surface of the first housing 510 and located at one side of the accommodation cavity 511. The first upper cover 520 is connected, at its bottom, to the mounting surface 512 so as to fix and connect the first upper cover 520 to the first housing 510 via the mounting surface 512.

In some embodiments, as shown in FIG. 10, the other end of the first housing 510 is formed, at one side thereof, with a cut-off corner (or referred to as a recessed corner), and is formed, at the other side thereof, with a protruding structure. One side of the protruding structure away from the cut-off corner is provided with a connection hole communicated with the accommodation cavity 511, and a light reception component is connected to the first housing through the connection hole. In this way, in cases of providing the same number of light reception components on the first housing 510, the first housing 510 designed as mentioned above effectively reduces the volume of the first housing 510 compared to a case in which the first housing is designed to have a relatively regular structure, which in turn makes it easier to control the size of the first cavity member and save space occupied by the first cavity member in the optical module.

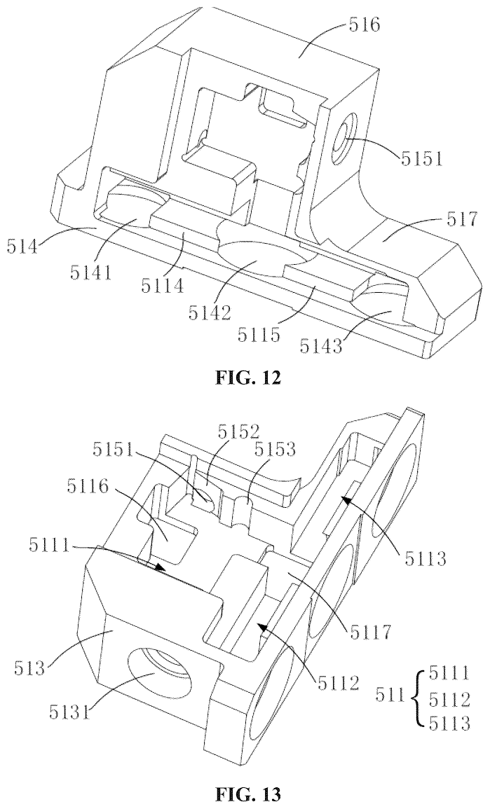

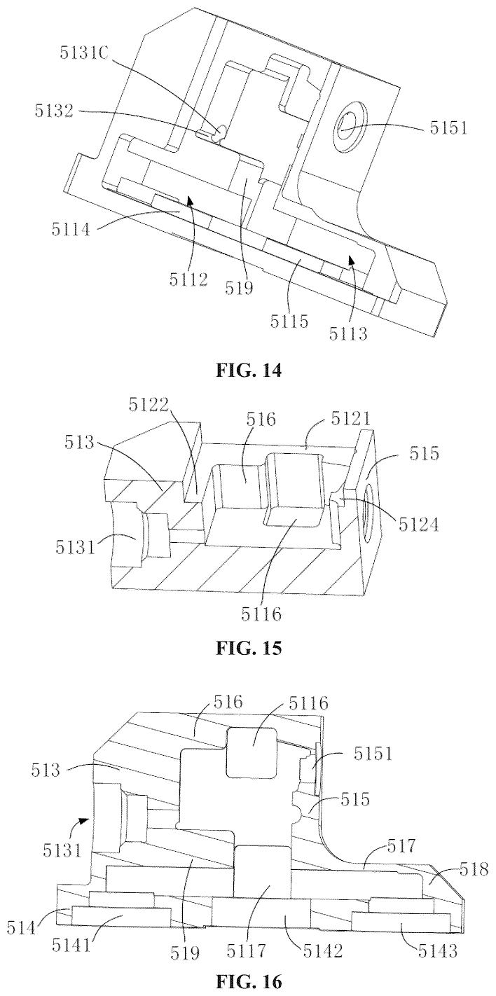

FIG. 11 is a first structural schematic diagram of a first housing provided according to some embodiments of the present disclosure, FIG. 12 is a second structural schematic diagram of a first housing provided according to some embodiments of the present disclosure, FIG. 13 is a third structural schematic diagram of a first housing provided according to some embodiments of the present disclosure, FIG. 14 is a fourth structural schematic diagram of a first housing provided according to some embodiments of the present disclosure, FIG. 15 is a first sectional diagram of a first housing provided according to some embodiments of the present disclosure, and FIG. 16 is a second sectional diagram of a first housing provided according to some embodiments of the present disclosure. FIGS. 11 to 16 illustrate the structure of the first housing 510 in detail.

In some embodiments, the first housing 510 includes a first side plate 513, a second side plate 514, a third side plate 515 and a fourth side plate 516 located at periphery of the accommodation cavity 511. The first side plate 513 is located on a first side of the first housing 510, the second side plate 514 is located on a second side of the first housing 510, the third side plate 515 is located on a third side of the first housing 510, and the fourth side plate 516 is located on a fourth side of the first housing 510. The fourth side of the first housing 510 located is close to the lower side plate 2022 of the lower shell part 202 and is on a different side from the second side of the first housing 510. The first side plate 513 is provided with the fourth connection hole 5131; the second side plate 514 is provided with the first connection hole 5141, the second connection hole 5142 and the third connection hole 5143; and the third side plate 515 is provided with the fifth connection hole 5151. For example, the first side plate 513, the second side plate 514, the third side plate 515 and the fourth side plate 516 are integrally formed.

In some embodiments, the second side plate 514 is provided with the first connection hole 5141, the second connection hole 5142, and the third connection hole 5143 so as to arrange the first light reception component 530, the second light reception component 540 and the third light reception component 550, achieving independence among the first light reception component 530, the second light reception component 540 and the third light reception component 550, which can reduce high-frequency crosstalk, thermal crosstalk, and the like, among the first light reception component 530, the second light reception component 540, and the third light reception component 550.

In some embodiments, the first housing 510 further includes a fifth side plate 517 and a sixth side plate 518. The fifth side plate 517 is located between the second side plate 514 and the third side plate 515, with one end of the fifth side plate 517 connected to the third side plate 515, the other end of the fifth side plate 517 connected to one end of the sixth side plate 518, and the other end of the sixth side plate 518 connected to the second side plate 514. For example, an extension direction of the fifth side plate 517 is similar to that of the second side plate 514, and an extension direction of the sixth side plate 518 is similar to that of the third side plate 515. In some embodiments, the first housing 510 is provided with the fifth side plate 517 and the sixth side plate 518 in such a way that the cut-off corner is formed outside of the third side plate 515 of the first housing 510, and the arrangements of the second side plate 514, the fifth side plate 517 and the sixth side plate 518 enable the first housing 510 to have the protruding structure, which has an accommodation space, at a side of the cut-off corner. In this way, it not only allows that the accommodation cavity 511 has enough space for assembling the optical assembly 560 but also can effectively reduce a volume of the first housing 510 such that volumes of the optical transmission and reception components are controlled within an appropriate range, adapting to requirements of assembly space of the optical module 200.

In some embodiments, the accommodation cavity 511 includes a first accommodation cavity 5111, a second accommodation cavity 5112 and a third accommodation cavity 5113 which are communicated with each other so as to enable an optical signal to be transmitted from the first accommodation cavity 5111 to the second accommodation cavity 5112, and from the first accommodation cavity 5111 to the third accommodation cavity 5113.

In some embodiments, a baffle plate 519 is provided in the accommodation cavity 511, and the second accommodation cavity 5112 is surrounded and formed through the first side plate 513, the second side plate 514 and the baffle plate 519, and thus the baffle plate 519 is located between the first accommodation cavity 5111 and the second accommodation cavity 5112. One end of the baffle plate 519 is connected to the first side plate 513, and the second accommodation cavity 5112 is communicated with the first accommodation cavity 5111 at the other end of the baffle plate 519. The baffle plate 519 may provide, to some extent, isolation between the first accommodation cavity 5111 and the second accommodation cavity 5112, so as to reduce unnecessary transmission of optical signal from the first accommodation cavity 5111 to the second accommodation cavity 5112. For example, a length extension direction of the baffle plate 519 is parallel to a length extension direction of the second side plate 514. In some embodiments, the baffle plate 519 is integrally formed with the first side plate 513.

In some embodiments, the second side plate 514, the fifth side plate 517 and the sixth side plate 518 surround and define the third accommodation cavity 5113, and the third accommodation cavity 5113 is communicated with the first accommodation cavity 5111 at an edge of the third side plate 515.

In some embodiments, the mounting surface 512 includes a first mounting surface 5121, a second mounting surface 5122, a third mounting surface 5123 and a fourth mounting surface 5124. The first mounting surface 5121 is formed by a top surface of the fourth side plate 516, the second mounting surface 5122 is formed by an edge portion of a top of the first side plate 513 that is recessed towards a bottom of the first housing 510, the third mounting surface 5123 is a top surface of the baffle plate 519, the fourth mounting surface 5124 is formed by a inner edge portion of a top surface of the third side plate 515, a top surface of the fifth side plate 517 and a top surface of the sixth side plate 518, and the fourth mounting surface 5124 is located lower than an outer edge portion of the top surface of the third side plate 515. For example, the first mounting surface 5121, the second mounting surface 5122, the third mounting surface 5123 and the fourth mounting surface 5124 are respectively configured to fixedly connect with the first upper cover 520, and the first upper cover 520 is limited by an outer side of the first side plate 513 and an outer side of the third side plate 515, so as to facilitate fixed connection of the first upper cover 520 with the first housing 510, and to ensure stability of connection between the first upper cover 520 and the first housing 510.

In some embodiments, a first support platform 5114 is provided in the second accommodation cavity 5112, a second support platform 5115 is provided in the third accommodation cavity 5113, and the first support platform 5114 and the second support platform 5115 support and connect the first upper cover 520. For example, the first support platform 5114 and the second support platform 5115 are respectively provided on an inner wall of the second side plate 514, the first support platform 5114 is located between the first connection hole 5141 and the second connection hole 5142, and the second support platform 5115 is located between the second connection hole 5142 and the third connection hole 5143, such that a side surface of the first support platform 5114 may be used to mount and position optical devices arranged in the second accommodation cavity 5112, and a side surface of the second support platform 5115 may be used to mount and position optical devices arranged in the third accommodation cavity 5113.

In some embodiments, a top surface of the first support platform 5114 and a top surface of the second support platform 5115 are located lower than a top surface of the second side plate 514. The first upper cover 520 is supported and connected with the top surface of the first support platform 5114 and the top surface of the second support platform 5115, and is limited by and connected to the second side plate 514.

In some embodiments, a first support surface 5152 is provided on an inner wall of the third side plate 515, with the fifth connection hole 5151 penetrating through the first support surface 5152. The first support surface 5152 is provided to support and fix optical devices. For example, the first support surface 5152 is an inclined surface and is inclined from one end towards the other end along the inner wall of the third side plate 515, that is, a central axis of the fifth connection hole 5151 is not perpendicular to the first support surface 5152.

In some embodiments, the first accommodation cavity 5111 is also provided therein with a first recessed groove 5116. The first recessed groove is disposed on a bottom surface of the first housing 510, extends towards the fourth side plate 516 and is configured to dispose optical devices. By providing the first recessed groove 5116 on the bottom surface of the first accommodation cavity 5111, relative height between positions on the bottom of the first accommodation cavity 5111 may be adjusted, which facilitates disposing optical devices. For example, the first recessed groove 5116 extends to an inner wall of the fourth side plate 516, forming a recess on the fourth side plate 516, which facilitates to coordinate usage space of the first accommodation cavity 5111 during disposing devices through the first recessed groove 5116.

In some embodiments, the first accommodation cavity 5111 is provided therein with a second recessed groove 5117 at junctions between the first accommodation cavity and the second accommodation cavity 5112 as well as between the first accommodation cavity and the third accommodation cavity 5113. The second recessed groove 5117 is configured to dispose optical devices. The first accommodation cavity 5111 is provided with the second recessed groove 5117 at its bottom, a relative height between different positions on the bottom of the first accommodation cavity 5111 may thus be adjusted through the second recessed groove 5117, which facilitates arranging optical devices.

In some embodiments, a first avoidance groove 5132 is provided on an inner wall of the first side plate 513, which is configured to make way for optical devices so as to facilitate assembling, such as positioning and glue-dispensing, of the optical assembly in the first accommodation cavity 5111. In some embodiments, the inner wall of the first side plate 513 is not limited to include one first avoidance groove 5132, and may include a plurality of first avoidance grooves 5132.

In some embodiments, the third side plate 515 is also provided, in the inner wall thereof, with a second avoidance groove 5153, which is configured to make way for optical devices so as to facilitate assembling, such as positioning and glue-dispensing, of optical assembly in the first accommodation cavity 5111. In some embodiments, the inner wall of the third side plate 515 is not limited to include one second avoidance groove 5153, and may include a plurality of second avoidance grooves 5153.

In some embodiments, the first connection hole 5141, the second connection hole 5142, the third connection hole 5143 and the fifth connection hole 5151 may be stepped through holes for convenient use of the first connection hole 5141, the second connection hole 5142, the third connection hole 5143 and the fifth connection hole 5151.

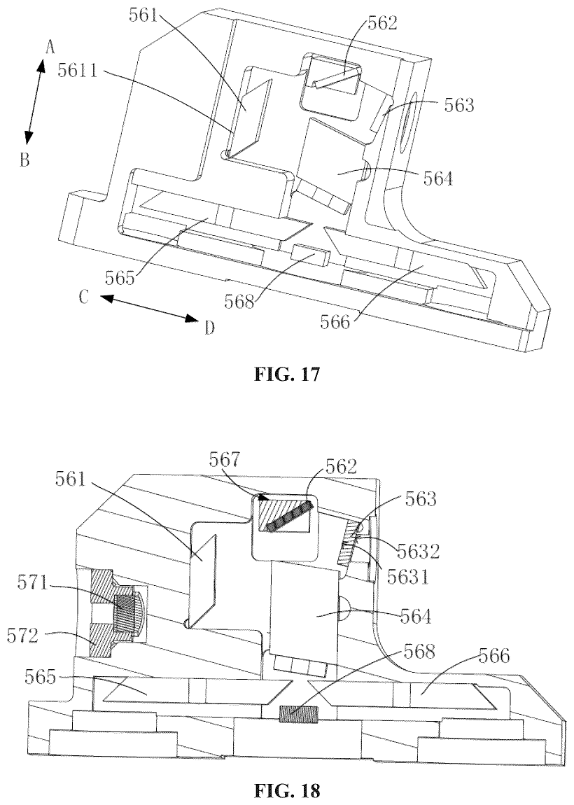

FIG. 17 is a diagram of a first housing provided according to some embodiments of the present disclosure in a usage state, FIG. 18 is sectional diagram of a first housing provided according to some embodiments of the present disclosure in a usage state. FIGS. 17 and 18 show an assembling form of the optical assembly 560 on the first housing 510 in detail. As shown in FIGS. 17 and 18, the optical assembly 560 includes a first displacement prism 561, a reflector 562, a first filter 563, a first wavelength division multiplexer 564, a second displacement prism 565 and a third displacement prism 566. The first displacement prism 561, the reflector 562, the first filter 563, the first wavelength division multiplexer 564, the second displacement prism 565 and the third displacement prism 566 are arranged in the accommodation cavity 511.

In some embodiments, the first displacement prism 561 is configured to adjust a position of optical signals in a A-B direction of the first housing 510, so as to adapt to the requirements of the optical module on assembling position of the optical fiber adapter 700, and to provide enough space to dispose the reflector 562 and the first filter 563.

In some embodiments, a first reflective surface 5613 of the first displacement prism 561 is located in an optical path of the optical fiber adapter 700, for example, the first displacement prism 561 is located at an edge of the fourth connection hole 5131, allowing the optical signal transmitted through the fourth connection hole 5131 to be transmitted to the first displacement prism 561, and the optical signal output from the first displacement prism 561 to be transmitted into the fourth connection hole 5131. For example, a first side 5611 of the first displacement prism 561 is disposed against the inner wall of the first side plate 513, or the first side 5611 of the first displacement prism 561 is hermetically connected to the fourth connection hole 5131. The first avoidance groove 5132 avoids or makes way for an end of the first displacement prism 561, facilitating a compact arrangement of the first displacement prism 561 in the first accommodation cavity 5111.

In some embodiments, the first side 5611 of the first displacement prism 561 is perpendicular or approximately perpendicular to the central axis of the fourth connection hole 5131, such that the optical signal incident on the first side 5611 through the fourth connection hole 5131 is transmitted perpendicularly or approximately perpendicularly to the first side 5611, and the optical signal output from the first side 5611 can be transmitted along the central axis of the fourth connection hole 5131 into the fourth connection hole 5131. For example, the first side 5611 seals the rear hole 5131C, the optical axis of the lens 571 is perpendicular to the first side 5611, the first reflective surface of the first displacement prism 561 covers the rear hole 5131C, and an angle between the optical axis of the lens 571 and the first reflective surface is 45°.

In some embodiments, the first filter 563 is located in an optical path of the light emission component, is disposed on the first support surface 5152, and covers the fifth connection hole 5151. The optical signal output by the light emission component 400 is transmitted to the first filter 563. The optical signal output by the light emission component 400 pass through the first filter 563, and is transmitted to a second side 5612 of the first displacement prism 561. The first filter 563 is also configured to reflect the optical signal output from the second side 5612 of the first displacement prism 561 to the reflector 562. For example, the first filter 563 is located in a reflective optical path of the second reflective surface of the first displacement prism 561, and the reflector 562 is located in a reflective optical path of the first filter 563. For example, a first surface 5631 of the first filter 563 faces the first displacement prism 561, and a second surface 5632 of the first filter 563 is disposed against the first support surface 5152.

In some embodiments, the reflector 562 is disposed within the first recessed groove 5116, and is configured to reflect the optical signal reflected by the first filter 563 to the first wavelength division multiplexer 564. In order to facilitate the reflection of optical signal from the reflector 562 to the first wavelength division multiplexer 564, the reflector 562 is inclinedly disposed in the first accommodation cavity 5111, and a reflective surface 5621 of the reflector 562 is not parallel to the second side 5612 of the first displacement prism 561 and has an angle of less than 90° with respect to the second side 5612 of the first displacement prism 561. In some embodiments, an inclined second support surface is provided on an inner wall of the fourth side plate 516, and a back of the reflector 562 is disposed against the second support surface. The second support surface is configured to inclinedly dispose the reflector 562 in the first accommodation cavity 5111.

In some embodiments, a side of the first wavelength division multiplexer 564 is disposed against the inner wall of the third side plate 515, the side of the first wavelength division multiplexer 564 contacts the second avoidance groove 5153. The second avoidance groove 5153 is configured to avoids or make way for the first wavelength division multiplexer 564 to facilitate positioning and assembling of the first wavelength division multiplexer 564.

In some embodiments, the optical assembly 560 further includes a reflector bracket 567, with a bottom of the reflector bracket 567 disposed in the first recessed groove 5116, and a support mechanism, such as a support slope, is provided on the reflector bracket 567. The support mechanism supports and connects with the reflector 562, such that the reflector 562 is inclinedly disposed in the first accommodation cavity 5111. It is convenient to adjust the position of the reflector 562 during optical path coupling of the optical assembly 560.

In some embodiments, the first wavelength division multiplexer 564 is disposed at the bottom of the first accommodation cavity 5111, with a light entering side of the first wavelength division multiplexer 564 facing the reflector 562, that is, the first wavelength division multiplexer 564 is located in the reflective optical path of the reflector 562, and a light existing side of the first wavelength division multiplexer 564 facing the second side plate 514. The first wavelength division multiplexer 564 is configured to split the optical signal reflected by the reflector 562 according to wavelengths. For example, the first wavelength division multiplexer 564 splits a beam of optical signals including the fourth, fifth, and sixth wavelengths into three beams according to the wavelengths. For example, the first wavelength division multiplexer 564 splits the optical signals reflected by the reflector 562 into the fourth-wavelength optical signal, the fifth-wavelength optical signal, and sixth-wavelength optical signal.

In some embodiments, the second displacement prism 565 is disposed in the second accommodation cavity 5112, and the fourth-wavelength optical signal output from the first wavelength division multiplexer 564 is transmitted to the second displacement prism 565; the third displacement prism 566 is disposed in the third accommodation cavity 5113, and the sixth-wavelength optical signal output from the first wavelength division multiplexer 564 is transmitted to the third displacement prism 566. The second displacement prism 565 and the third displacement prism 566 are configured to adjust the positions of the optical signals in a C-D direction of the first housing 510, such that the optical signals split by the first wavelength division multiplexer 564 can be transmitted to the corresponding first light reception component 530, second light reception component 540, and third light reception component 550.

In some embodiments, a side of the first support platform 5114 is fixedly connected to a second side of the second displacement prism 565, and a side of the second support platform 5115 is fixedly connected to the third displacement prism 566.

In some embodiments, multiple second filters are disposed in the second accommodation cavity 5112 and the third accommodation cavity 5113, for example, they are arranged at an output end of the second displacement prism 565 and at an output end of the third displacement prism 566. The second filter is configured to filter the optical signal before the optical signal is input to the corresponding optical reception component, so as to reduce noise wave in the optical signal of the corresponding wavelength and ensure optical signal reception quality. For example, the second filter 568 is provided in the second recessed groove 5117 and is located at an end of the second connection hole 5142. The second filter 568 is located in front of a light entering end of the second light reception component 540 and is configured to filter noise wave in the optical signal to be transmitted to the second light reception component 540, thereby improving the quality of the optical signal transmitted to the second light reception component 540.

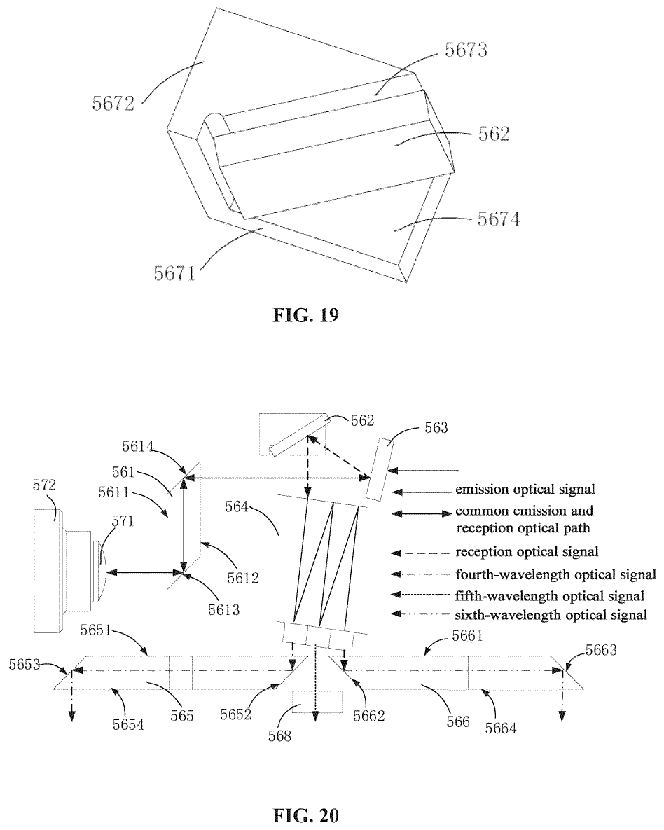

FIG. 19 is a diagram of a reflector bracket provided according to some embodiments of the present disclosure in a usage state. As shown in FIG. 19, the reflector bracket 567 includes a bracket base 5671 and a bracket support portion 5672 provided on a top of the bracket base 5671. The bracket support portion 5672 is provided thereon with a support slope 5673, and the top of the bracket base 5671 has a support surface 5674. The support slope 5673 and the support surface 5674 support and connect with the reflector 562. A bottom of the bracket base 5671 is connected to the first recessed groove 5116. For example, in a direction shown in FIG. 19, the support slope 5673 supports and connects with a back surface of the reflector 562, and the support surface 5674 supports and connects with a bottom surface of the reflector 562. In this way, the provision of the reflector bracket 567 facilitates the assembling of the reflector 562 in the first housing 510.

FIG. 20 illustrates a diagram of an optical assembly according to some embodiments of the present disclosure in a combined state, and shows transmission optical paths of optical signals in the optical assembly. As shown in FIG. 20, emission optical signals output by the light emission component 400 pass through the first filter 563 and are transmitted to the second side 5612 of the first displacement prism 561, the emission optical signals are transmitted to the second reflective surface 5614 through the second side surface 5612 and are reflected to the first reflective surface 5613 by the second reflective surface 5614, and the emission optical signals are reflected to the first side surface 5611 by the first reflective surface 5613 and are then transmitted to the lens assembly 570 through the first side surface 5611, through which the optical signals are converged.

As shown in FIG. 20, a beam of reception optical signals including the fourth, fifth, and sixth wavelengths is collimated through the lens assembly 570 and is transmitted to the first side surface 5611, is transmitted to the first reflective surface 5613 after passing through the first side 5611, is reflected by the first reflective surface 5613 to the second reflective surface 5614, and is reflected by the second reflective surface 5614 to the second side surface 5612 and passes through the second side 5612; the beam of reception optical signals is transmitted to the first filter 563, is reflected by the first filter 563 to the reflector 562, and is then reflected by the reflector 562 to the first wavelength division multiplexer 564; and the beam of reception optical signals transmitted to the first wavelength division multiplexer 564 is split into the fourth-wavelength optical signal, the fifth-wavelength optical signal and the sixth-wavelength optical signal according to wavelengths of optical signals.

The fourth-wavelength optical signal is transmitted to the first side surface 5651 of the second displacement prism 565, and then is transmitted to the first reflective surface 5652 after passing through the first side surface 5651, is reflected by the first reflective surface 5652 to the second reflective surface 5653, is reflected by the second reflective surface 5653 to the second side surface 5654, and then is transmitted to the first light reception component 530 after passing through the second side surface 5654. The fifth-wavelength optical signal is transmitted to the second light reception component 540 after passing through the second filter 568. The sixth-wavelength optical signal is transmitted to the first side surface 5661 of the third displacement prism 566, which passes through the first side surface 5661, and is transmitted to the first reflective surface 5662, is reflected by the first reflective surface 5662 to the second reflective surface 5663, and then is reflected by the second reflective surface 5663 to the second side surface 5664, and passes through the second side surface 5664 and then is transmitted to the third light reception component 550.

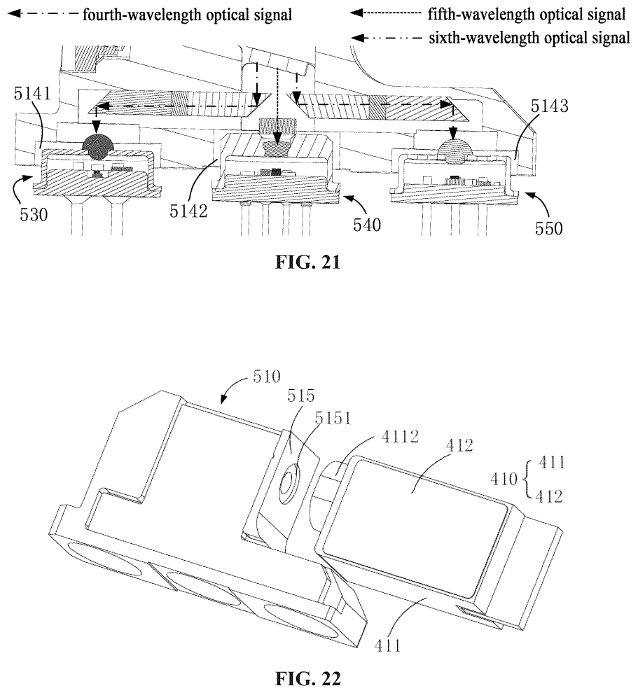

FIG. 21 is a sectional diagram showing an assembly of light reception components and the first housing provided according to some embodiments of the present disclosure. As shown in FIG. 21, a top of the first light reception component 530 is embedded into the first connection hole 5141, a top of the second light reception component 540 is embedded into the second connection hole 5142, and a top of the third light reception component 550 is embedded into the third connection hole 5143, achieving the isolation of the first light reception component 530, the second light reception component 540 and the third light reception component 550 through the separation of the first connection hole 5141, the second connection hole 5142 and the third connection hole 5143, which effectively reduces high-frequency crosstalk, thermal crosstalk, and other interference among the first light reception component 530, the second light reception component 540 and the third light reception component 550. For example, the first light reception component 530, the second light reception component 540 and the third light reception component 550 each include a cap, and these caps are embedded into the respective connection holes.

As shown in FIG. 21, the fourth-wavelength optical signal is transmitted to the first light reception component 530, the fifth-wavelength optical signal is transmitted to the second light reception component 540, and the sixth-wavelength optical signal is transmitted to the third light reception component 550. Of course, in some embodiments, the optical signal transmitted to the first light reception component 530 is not limited to the fourth-wavelength optical signal, and may also include optical signals of other wavelengths, but mainly include the fourth-wavelength optical signal. The optical signal transmitted to the second light reception component 540 is not limited to the fifth-wavelength optical signal, and may also include optical signals of other wavelengths, but mainly include the fifth-wavelength optical signal. The optical signal transmitted to the third light reception component 550 is not limited to the sixth-wavelength optical signal, and may also include optical signals of the other wavelengths, but mainly include the sixth-wavelength optical signal.

In some embodiments, the wavelength of the fourth-wavelength optical signal is smaller than that of the fifth-wavelength optical signal, and the wavelength of the fifth-wavelength optical signal is smaller than that of the sixth-wavelength optical signal. For example, the fourth-wavelength optical signal received by the first light reception component 530 has a wavelength within a wavelength range of 1260 nm-1280 nm, such as 1270 nm; the fifth-wavelength optical signal received by the second light reception component 540 has a wavelength in a wavelength range of 1284 nm-1288 nm, such as 1286 nm; and the sixth-wavelength optical signal received by the third light reception component 550 has a wavelength in a wavelength of 1290 nm-1330 nm, such as 1310 nm.

Each of the first light reception component 530, the second light reception component 540 and the third light reception component 550 includes a photodetector, which is configured to receive an optical signal and convert it into an electrical signal. In some embodiments, a receiving rate of the photodetector in the second light reception component 540 is greater than that of the photodetector in the first light reception component 530, and is greater than that of the photodetector in the third light reception component 550, such that the fifth-wavelength optical signal with the highest transmission rate has a relatively short and simplest transmission optical distance from the first wavelength division multiplexer 564 to the corresponding photodetector, thus the photodetector in the second light reception component 540 can receive the optical signal with high coupling efficiency. For example, the photodetector in the first light reception component 530 has a receiving rate of 10G, the photodetector in the second light reception component 540 has a receiving rate of 50G, and the photodetector in the third light reception component 550 has a receiving rate of 2.5G.

FIG. 22 is an exploded schematic diagram of a first housing and a light emission component provided according to some embodiments of the present disclosure. As shown in FIG. 22, one end of the light emission component 400 is located in the cut-off corner of the first housing 510, with a side of the one end of the light emission component 400 close to the protruding structure of the first housing 510, achieving a compact assembly of the light emission component 400 and the optical accommodation component 500, which effectively reducing overall size of the light emission component 400 and the optical accommodation component 500.

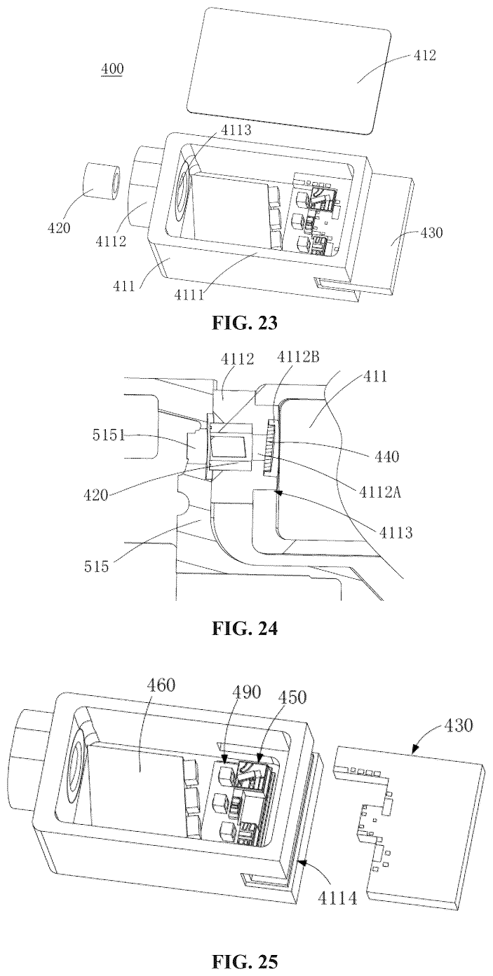

FIG. 23 is a first exploded schematic diagram of a light emission component provided according to some embodiments of the present disclosure. As shown in FIGS. 22 and 23, the light emission component 400 includes a second cavity member 410 which includes a second housing 411 and a second upper cover 412. The second housing 411 is formed therein with an inner cavity, and the second upper cover 412 is covered on and connected to the second housing 411, thereby forming a relatively sealed cavity structure with the second housing 411.

A connecting portion 4112 is provided on the one side of the second cavity member 410, through which the second cavity member 410 is connected to the first housing 510. With the connecting portion 4112, it is convenient for achieving the connection between the second cavity member 410 and the first housing 510. For example, one end of the connecting portion 4112 is connected to the third side plate 515, while the other end thereof is connected to the second housing 411, and the connecting portion 4112 is communicated with the fifth connection hole 5151 to achieve the communication between the first housing 510 and the second housing 411 through the connecting portion 4112. In some embodiments, a cross-sectional area of the connecting portion 4112 is smaller than an area of an outer wall of the third side plate 515 and is smaller than an area of the one side of the second housing 411. In this way, it not only can facilitate connection between the second housing 411 and the first housing 510, but also can ensure the sealing effect of the second cavity member 410.

In some embodiments, the connecting portion 4112 has a cylindrical outer contour. When the connecting portion 4112 is connected to the first housing 510 via laser welding, the cylindrical connecting portion 4112 facilitates the operation of the laser welding and thus facilitates connection between the connecting portion 4112 and the first housing 510.

As shown in FIG. 23, a top of the second housing 411 is provided with a fixing surface 4111, and the second upper cover 412 is fixedly connected to the fixing surface 4111. A first through hole 4113 is provided in the second housing 411, and the first through hole 4113 is communicated with the inner cavity of the second housing 411 and with the connecting portion 4112. The first through hole 4113 is communicated with the fifth connection hole 5151 via the connecting portion 4112. The first through hole 4113 is configured for transmitting optical signals.

In some embodiments, the light emission component 400 includes an isolator 420. For example, the isolator 420 is provided in the first through hole 4113. The isolator 420 seals the first through hole 4113 and is provided to prevent an optical signal output through the fifth connection hole 5151 in the first cavity member from being incident into the second cavity member 410. For example, the isolator 420 is provided to prevent the emission optical signal reflected back by the first filter 563 from returning to the second cavity member 410, or to prevent the reception optical signal passing through the first filter 563 from entering the second cavity member 410.

In some embodiments, a first circuit board 430 is disposed at the other end of the second housing 411, and is configured to achieve electrical connection between electrical elements in the second cavity member 410 and the circuit board 300. For example, the first circuit board 430 is embedded into the other end of the second housing 411, such that one end of the first circuit board 430 extends into the second housing 411, and the other end of the first circuit board 430 is located outside of the second housing 411. The first circuit board 430 is electrically connected to the circuit board 300 via a flexible circuit board. In some embodiments, the first circuit board 430 employs a ceramic board, but is not limited to the ceramic board.

FIG. 24 shows a connection state schematic diagram between a light emission component and a first housing provided according to some embodiments of the present disclosure. As shown in FIG. 24, the first through hole 4113 is provided in a side wall of the second housing 411, one end of the connecting portion 4112 is connected to the outer wall of the third side plate 515, and the other end of the connecting portion 4112 is embedded into the first through hole 4113. For example, the other end of the connecting portion 4112 is hermetically connected to the first through hole 4113. For example, a second through hole 4112A is provided in the connecting portion 4112, which runs through the connecting portion 4112 in a direction parallel to a central axis of the first through hole 4113, to communicate the fifth connection hole 5151 with the inner cavity of the second housing 411 through the second through hole 4112A. The isolator 420 is embedded into the second through hole 4112A.

In some embodiments, in a direction shown in FIG. 24, a left end face of the connecting portion 4112 contacts and connects with the outer wall of the third side plate 515, a left end face of the isolator 420 is located in the fifth connection hole 5151, and most of the isolator 420 is located in the second through hole 4112A. By positioning the isolator 420 in the fifth connection hole 5151 and the second through hole 4112A, it not only can facilitate connecting with the first housing 510 via the connecting portion 4112, but also can effectively control a packaging size of the optical emission component 400, thereby facilitating assembling the optical emission component 400 in the optical module.

In some embodiments, the light emission component 400 also includes an optical window 440, which is configured to allow optical signals to pass through and seal the through hole. For example, the optical window 440 is embedded into the second through hole 4112A to seal the second through hole 4112A; and the optical window 440 may be made of transparent glass. The optical window 440 is provided to relatively seal the second through hole 4112A, which can facilitate the transmission of optical signals as well as the sealing of the second through hole 4112A, to ensure the sealing of the second cavity member 410. The optical window 440 may also be embedded into and connected to the first through hole 4113.

In some embodiments, the optical window 440 is inclinedly disposed within the second through hole 4112A and is located at an end of the second through hole 4112A away from the isolator 420. Furthermore, by arranging the optical window 440 in a direction not perpendicular to the central axis of the first through hole 4113, it is possible to reduce returning of the emission optical signals reflected by the optical window 440 to the transmission light path of the emission optical signals. For example, the end of the connecting portion 4112 that is embedded into the first through hole 4113 is provided with an installation groove 4112B. A bottom of the installation groove 4112B is communicated with the second through hole 4112A, and a bottom surface of the installation groove 4112B is an inclined surface. The optical window 440 is disposed in the installation groove 4112B, and a transparent surface of the optical window 440 is connected to the bottom surface of the installation groove 4112B. For example, the bottom surface of the installation groove 4112B has an inclination angle of 2°˜7°.

FIG. 25 is a second exploded schematic diagram of a light emission component provided according to some embodiments of the present disclosure. As shown in FIG. 25, the other end of the second housing 411 is provided with an opening 4114, which runs through the other end of the second housing 411. One end of the first circuit board 430 is embedded into the opening 4114, that is, one end of the first circuit board 430 passes through the opening 4114 and extends into the inner cavity of the second housing 411.

In some embodiments, a laser assembly 450 is disposed in the inner cavity of the second housing 411, and is located close to the one end of the first circuit board 430, to facilitate the electrical connection of the laser assembly 450 to the first circuit board 430. The laser assembly 450 is configured to emit multiple paths of optical signals of different wavelengths. For example, the laser assembly 450 is connected to the first circuit board 430 by wire bonding.

In some embodiments, a second wavelength division multiplexer 460 is disposed in the inner cavity of the second housing 411, which is configured to combine the multiple paths of optical signals of different wavelengths emitted by the laser assembly 450 into one path of emission optical signal.

In some embodiments, the light emission component 400 also includes a collimating lens 490 provided in an optical path from the laser assembly 450 to the second wavelength division multiplexer 460, for collimating the optical signal generated by the laser assembly 450 and transmitting it to a light inlet of the second wavelength division multiplexer 460.

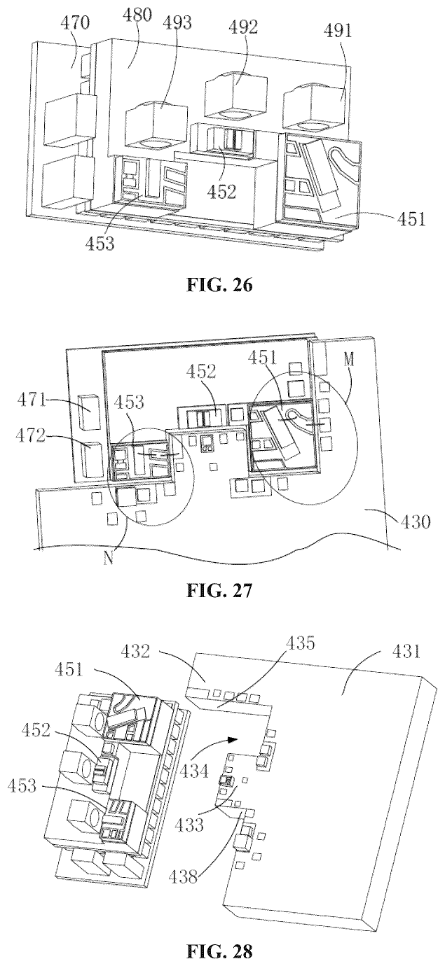

FIG. 26 is a partial structural schematic diagram of a light emission component provided according to some embodiments of the present disclosure. In some embodiments, as shown in FIG. 26, the laser assembly 450 includes a first laser assembly 451, a second laser assembly 452 and a third laser assembly 453; the second laser assembly 452 is located between the first laser assembly 451 and the third laser assembly 453, and light exiting directions of the first laser assembly 451, the second laser assembly 452 and the third laser assembly 453 face the second wavelength division multiplexer 460. In some embodiments, the first laser assembly 451 emits the first-wavelength optical signal, the second laser assembly 452 emits the second-wavelength optical signal, and the third laser assembly 453 emits the third-wavelength optical signal. Optical axes of the first-wavelength optical signal, the second-wavelength optical signal and the third-wavelength optical signal are parallel to a length extension direction of the second housing. For example, the first-wavelength optical signal has a wavelength in a range of 1340 nm-1344 nm, for example 1342 nm; the second-wavelength optical signal has a wavelength in a range of 1480 nm-1500 nm, for example 1490 nm; and the third-wavelength optical signal has a wavelength in a range of 1575 nm-1580 nm, for example 1577 nm.

In some embodiments, a transmission rate of the first laser assembly 451 is greater than that of the third laser assembly 453, and the transmission rate of the third laser assembly 453 is greater than that of the second laser assembly 452. For example, the first laser assembly 451 has a transmission rate of 50G, the second laser assembly 452 has a transmission rate of 2.5G, and the third laser assembly 453 has a transmission rate of 10G.

In some embodiments, light output end faces of the first laser assembly 451, the second laser assembly 452 and the third laser assembly 453 are not flush, that is, the light output end faces of the first laser assembly 451, the second laser assembly 452 and the third laser assembly 453 are located in different planes along the length of the second housing 411.

In some embodiments, the light emission component 400 also includes a thermos electric cooler (TEC) 470, the TEC 470 is located below the laser assembly 450 and is provided to adjust a temperature of the laser assembly 450.

In some embodiments, the light emission component 400 further includes a support plate 480, a top of the TEC 470 is fixedly connected to the support plate 480, and the first laser assembly 451, the second laser assembly 452 and the third laser assembly 453 are provided on the support plate 480.

In some embodiments, the collimating lens 490 includes a first collimating lens 491, a second collimating lens 492 and a third collimating lens 493, with the first collimating lens 491 being disposed in a transmission optical path from the first laser assembly 451 to the second wavelength division multiplexer 460, the second collimating lens 492 disposed in a transmission optical path from the second laser assembly 452 to the second wavelength division multiplexer 460, and the third collimating lens 493 disposed in a transmission optical path from the third laser assembly 453 to the second wavelength division multiplexer 460. In some embodiments, the first collimating lens 491, the second collimating lens 492 and the third collimating lens 493 are disposed on the support plate 480. Of course, in the embodiments of the present disclosure, the first collimating lens 491, the second collimating lens 492 and the third collimating lens 493 are not limited to be disposed on the support plate 480.

FIG. 27 is a second partial structural schematic diagram of a light emission component provided according to some embodiments of the present disclosure. As shown in FIG. 27, in some embodiments, the first laser assembly 451, the second laser assembly 452 and the third laser assembly 453 are packaged in a manner of Chip-On-Carrier (COC, also referred to as “chip mounting on ceramic substrate”). Therefore, sides of the first laser assembly 451, the second laser assembly 452 and the third laser assembly 453 have relatively regular contours, for example, the sides of the first laser assembly 451, the second laser assembly 452 and the third laser assembly 453 have rectangular contours, respectively.

In some embodiments, in a direction as shown in FIG. 28, the left end of the first circuit board 430 is formed with a plurality of extensions spaced at intervals, forming a plurality of side faces at the left end of the first circuit board 430. The plurality of side faces are configured to adapt to and assemble with sides of the first laser assembly 451, the second laser assembly 452 and the third laser assembly 453, so as to increase proximity of the first circuit board 430 to the first laser assembly 451, the second laser assembly 452 and the third laser assembly 453, and to make the left end of the first circuit board 430 surround the first laser assembly 451, the second laser assembly 452 and the third laser assembly 453. The left end of the first circuit board 430 is provided, on top edge thereof, with a plurality of pads, which are distributed on edges of the side faces of the left end of the first circuit board 430 to facilitate wire bonding of the first laser assembly 451, the second laser assembly 452 and the third laser assembly 453 to the corresponding pads. For example, three sides of the first laser assembly 451 are close to three side faces of the left end of the first circuit board 430, such that the left end of the first circuit board 430 is located at the sides of the first laser assembly 451 in a semi-enclosed manner; one side of the second laser assembly 452 is close to one side face of the left end of the first circuit board 430; and two sides of the third laser assembly 453 are close to two side faces of the left end of the first circuit board 430.

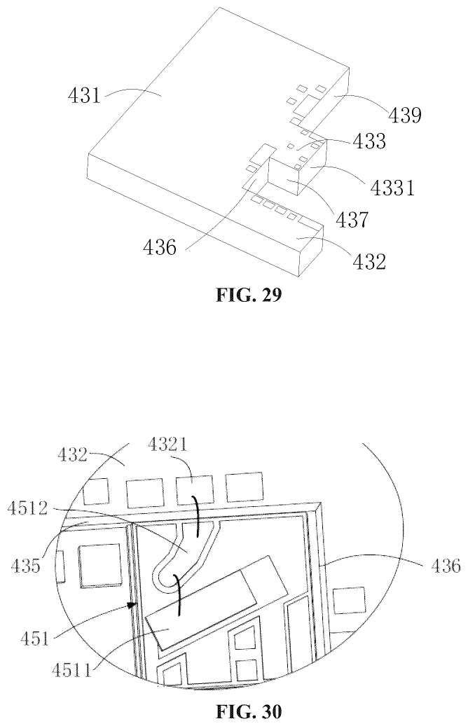

FIG. 28 is a partially exploded schematic diagram of an optical emission component provided according to some embodiments of the present disclosure, and FIG. 29 is a structural schematic diagram of a first circuit board provided according to some embodiments of the present disclosure. As shown in FIGS. 28 and 29, the first circuit board 430 includes a first circuit board body 431 and first and second extensions 432, 433 located at one end of the first circuit board body 431. The first extension 432 is located at an edge of the first circuit board 430, the second extension 433 is located in the middle of the first circuit board 430, and a second spacing 434 is formed between the first extension 432 and the second extension 433. The end of the first circuit board body 431 is formed with a first side face 435, a second side face 436, a third side face 437, a fourth side face 4331, a fifth side face 438 and a sixth side face 439. The first side face 435 is located on an edge of the first extension 432 that is close to the second spacing 434. The second side face 436 is located on a bottom of the second spacing 434. The third side face 437, the fourth side face 4331 and the fifth side face 438 are located on edges of the second extension 433. The sixth side face 439 is located at a side of the second extension 433 that is away from the first extension 432 and is connected to the fifth side face 438.

The first side face 435, the second side face 436 and the third side face 437 surround sides of the first laser assembly 451 such that three sides of the first laser assembly 451 are correspondingly close to the first side face 435, the second side face 436 and the third side face 437. The fourth side face 4331 is located at a side of the second laser assembly 452 such that one side of the second laser assembly 452 is close to the fourth side face 4331. The fifth side face 438 and the sixth side face 439 surround sides of the third laser assembly 453 such that two sides of the third laser assembly 453 are correspondingly close to the fifth side face 438 and the sixth side face 439.

The plurality of pads are provided at the edges of the top surface of the first circuit board 430 that connect with the first side 435, the second side 436, the third side 437, the fourth side 4331, the fifth side 438 and the sixth side 439, and the first laser assembly 451, the second laser assembly 452 and the third laser assembly 453 are correspondingly wire bonded to some of the pads at the edges of the top surface of the first circuit board 430. The other pads are provided to mount electrical devices, such as backlight detectors, resistors, capacitors, etc.

FIG. 30 is a partially enlarged diagram of the area indicated by the letter Min FIG. 27. As shown in FIG. 30, the first laser assembly 451 includes a first laser chip 4511 and a first high-frequency transmission line 4512. The first high-frequency transmission line 4512 is a metal layer formed on the substrate of the first laser assembly 451 and extends towards the first side face 435. The first extension 432 is provided, on an edge of a top surface thereof, with a first pad 4321, and the first pad 4321 is located at an edge of the first side face 435. One end of the first high-frequency transmission line 4512 is connected to the first laser chip 4511 by wire bonding, and the other end of the first high-frequency transmission line 4512 is connected to the first pad 4321 by wire bonding, so as to control a wire bonding length between the first laser chip 4511 and the first circuit board 430, for example, to control the wire bonding length between the first laser chip 4511 and the first circuit board 430 to be the shortest; and so as to ensure impedance matching between the first laser chip 4511 and the first circuit board 430. In some embodiments, the first high-frequency transmission line 4512 is located at the same height as the first pad 4321, facilitating the wire bonding of the first high-frequency transmission line 4512 to the first pad 4321 and controlling the wire bonding length within the shortest range.

In some embodiments, the first laser chip 4511 is an electrical absorption modulated laser (EML), and is packaged with a semiconductor laser amplifier. One end of the first high-frequency transmission line 4512 is connected, by wire bonding, to a positive electrode of an electric absorption modulator of the EML.

In some embodiments, the first laser chip 4511 is obliquely arranged, but a direction of the first-wavelength optical signal output by the first laser chip 4511 is parallel to a length direction of the second housing 411, in order to prevent a part of the optical signals generated by the first laser chip 4511 but reflected back by the first collimating lens 491 from entering the first laser chip 4511, thereby effectively reducing the reflected optical signals from entering the first laser chip 4511 and thus interfering with light emission of the first laser chip 4511.

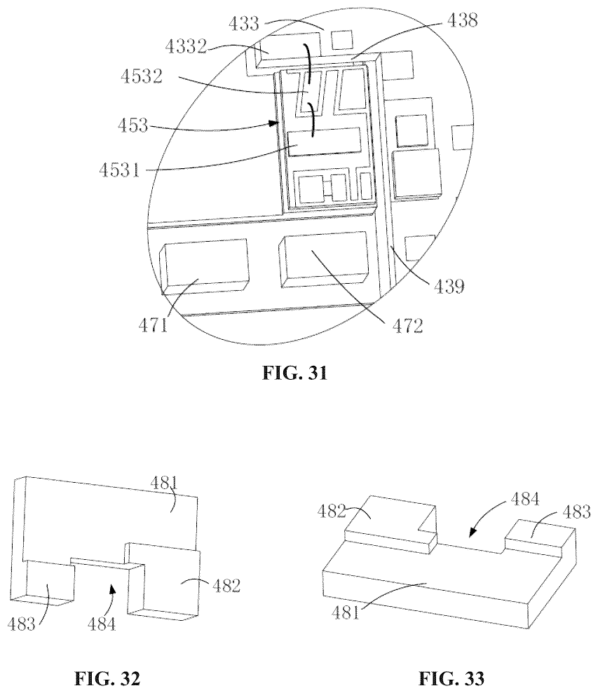

FIG. 31 is a partially enlarged diagram of the structure indicated by the letter N in FIG. 27. As shown in FIG. 31, the third laser assembly 453 includes a third laser chip 4531 and a second high-frequency transmission line 4532. The second high-frequency transmission line 4532 is a metal layer formed on the substrate of the third laser assembly 453, and the second high-frequency transmission line 4532 extends towards the fifth side face 438. The second extension 433 is provided, at an edge of a top surface thereof, with a second pad 4332, and the second pad 4332 is located at an edge of the fifth side face 438. One end of the second high-frequency transmission line 4532 is connected, by wire bonding, to the third laser chip 4531, and the other end of the second high-frequency transmission line 4532 is connected, by wire bonding, to the second pad 4332, so as to control a wire bonding length between the third laser chip 4531 and the first circuit board 430, for example, to control the wire bonding length between the third laser chip 4531 and the first circuit board 430 within the shortest range, and so as to ensure impedance matching between the third laser chip 4531 and the first circuit board 430. In some embodiments, the second high-frequency transmission line 4532 is located at the same height as the second pad 4332, thereby facilitating the wire bonding of the second high-frequency transmission line 4532 with the second pad 4332 and controlling the wire bonding length within the shortest range.

In some embodiments, the third laser chip 4531 is an EML, and one end of the second high-frequency transmission line 4532 is connected, by wire bonding, to a positive pole of an electric absorption modulator of the EML.

In some embodiments, the TEC 470 includes a first electrode 471 and a second electrode 472 which are located at an edge of the TEC 470. For example, the first electrode 471 and the second electrode 472 are provided on a side of the third laser assembly 453 that is away from the second laser assembly 452, and near the sixth side face 439.

As shown in FIGS. 27 to 31, in some embodiments, the arrangement of the first laser assembly 451, the second laser assembly 452 and the third laser assembly 453, together with the configuration of the first circuit board 430, allows to fully make use of the space of the second housing 411, thereby facilitating the provision of the first laser assembly 451, the second laser assembly 452 and the third laser assembly 453 inside the second housing 411, and achieving electrical connection of the circuit board 300 with each of the first laser assembly 451, the second laser assembly 452 and the third laser assembly 453.

FIG. 32 is a first structural schematic diagram of a support plate provided according to some embodiments of the present disclosure, and FIG. 33 is a second structural schematic diagram of a support plate provided according to some embodiments of the present disclosure. As shown in FIGS. 32 and 33, the support plate 480 comprises a support plate body 481, with a first spacing 484 formed at one side of the support plate body 481, a first boss 482 provided at one side of the first spacing 484 and on a top of the support plate body 481, and a second boss 483 provided at the other side of the first spacing 484 and on the top of the support plate body 481. Heights of the first boss 482 and the second boss 483 each is higher than a top surface of the support plate body 481. In some embodiments, the first boss 482 and the second boss 483 have different heights.

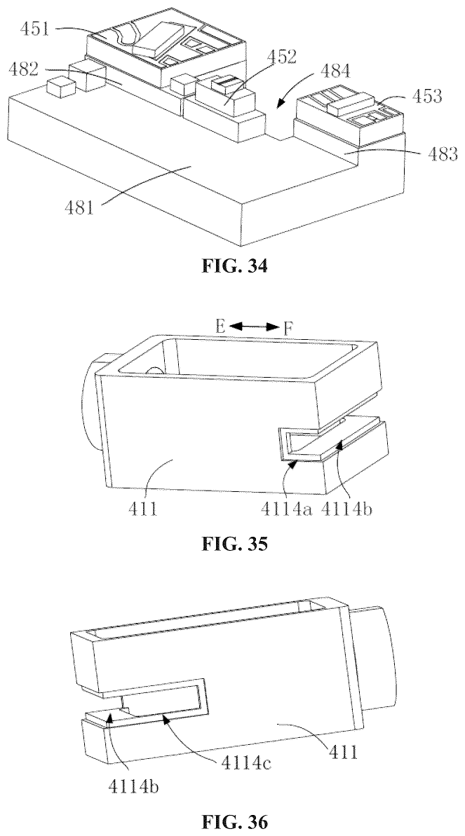

FIG. 34 is a diagram of a support plate provided according to some embodiments of the present disclosure in a usage state. As shown in FIG. 34, the first laser assembly 451 is provided on the first boss 482, the second laser assembly 452 is provided on the top surface of the support plate body 481 and close to an edge of the first spacing 484, and the third laser assembly 453 is provided on the second boss 483. The first boss 482 and the second boss 483 are configured to adapt to heights of optical signals output by the first laser assembly 451, the second laser assembly 452 and the third laser assembly 453, that is, to ensure that the optical signals output by the first laser assembly 451, the second laser assembly 452 and the third laser assembly 453 are at the same or similar height. In addition, the first boss 482 and the second boss 483 are configured to coordinate heights of pads provided on the first laser assembly 451, the second laser assembly 452 and the third laser assembly 453, so as to control the wire bonding lengths between them and the first circuit board 430. In addition, the provision of the first spacing 484 between the first boss 482 and the second boss 483 facilitates achieving thermal isolation among the first laser assembly 451, the second laser assembly 452 and the third laser assembly 453, and facilitates their assembling with the first circuit board 430, and saving assembling space.

FIG. 35 is a first structural schematic diagram of a second housing provided according to some embodiments of the present disclosure, and FIG. 36 is a second structural schematic diagram of a second housing provided according to some embodiments of the present disclosure. As shown in FIGS. 35 and 36, one side of the second housing 411 is formed with a first opening 4114a, one side of the second housing 411 is formed with a second opening 4114b, and another side of the second housing 411 is formed with a third opening 4114c. The first opening 4114a, the second opening 4114b and the third opening 4114c are sequentially connected, and each of the first opening 4114a, the second opening 4114b and the third opening 4114c is communicated with the inner cavity of the second housing 411. The first opening 4114a, the second opening 4114b and the third opening 4114c form a U-shaped opening 4114, and an extension length of the first opening 4114a in a E-F direction of the second housing 411 is smaller than an extension length of the third opening 4114c in the E-F direction of the second housing 411 so as to facilitate the assembly and connection of the first circuit board 430 in the opening 4114. An edge portion of the first circuit board body 431 is assembled and connected in the first opening 4114a, a middle portion of the first circuit board body 431 is assembled and connected in the second opening 4114b, and the edge portion of the first circuit board body 431, where the first extension 432 is located, is assembled and connected in the third opening 4114c.

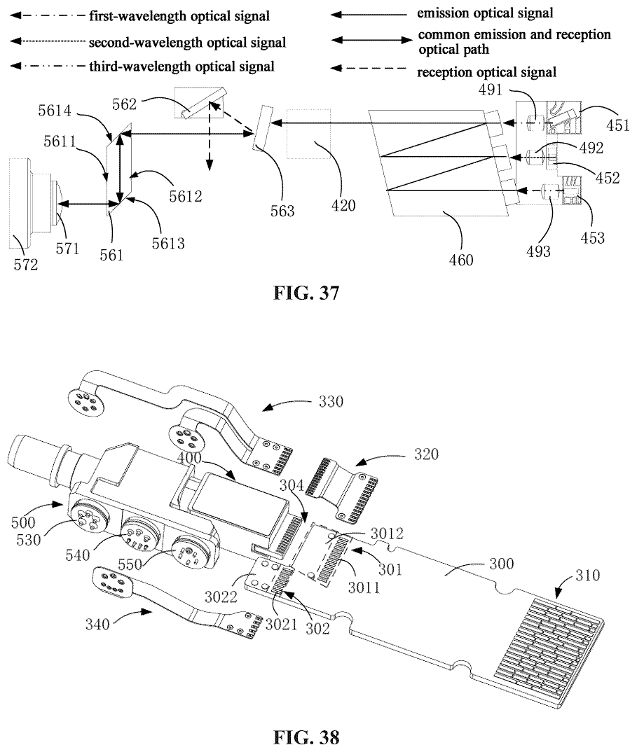

FIG. 37 is a diagram illustrating an optical path of an emission optical signal provided according to some embodiments of the present disclosure. As shown in FIG. 37, the first-wavelength optical signal emitted by the first laser assembly 451 is transmitted to the first collimating lens 491, collimated by the collimating lens 491, and is then transmitted to the second wavelength division multiplexer 460; the second-wavelength optical signal emitted by the second laser assembly 452 is transmitted to the second collimating lens 492, collimated by the second collimating lens 492, and is then transmitted to the second wavelength division multiplexer 460; and the third-wavelength optical signal emitted by the third laser assembly 453 is transmitted to the third collimating lens 493, where it is collimated, and is then transmitted to the second wavelength division multiplexer 460. The second wavelength division multiplexer 460 combines the first-wavelength optical signal, the second-wavelength optical signal and the third-wavelength optical signal into a beam of emission optical signals, which then is output to the isolator 420, the beam of emission optical signals passes through the isolator 420 and through the fifth connection hole 5151 to the first filter 563, and then passes through the first filter 563.

In the optical module provided according to the embodiments of the present disclosure, the optical emission component 400, the first light reception component 530, the second light reception component 540 and the third light reception component 550 are assembled and connected with the first housing 510, and the optical assembly 560 is disposed in the second cavity member 410, such that the optical module can emit a beam of emission optical signals including the first-wavelength optical signal, the second-wavelength optical signal and the third-wavelength optical signal via the fiber adapter 700, as well as receive a beam of reception optical signals including the fourth-wavelength optical signal, the fifth-wavelength optical signal and the sixth-wavelength optical signal via the fiber adapter 700, thereby enabling the optical module to emit optical signals having three different wavelengths and receive optical signals having three different wavelengths, which achieves integration of emission and reception of multi-wavelength optical signals in the optical module.

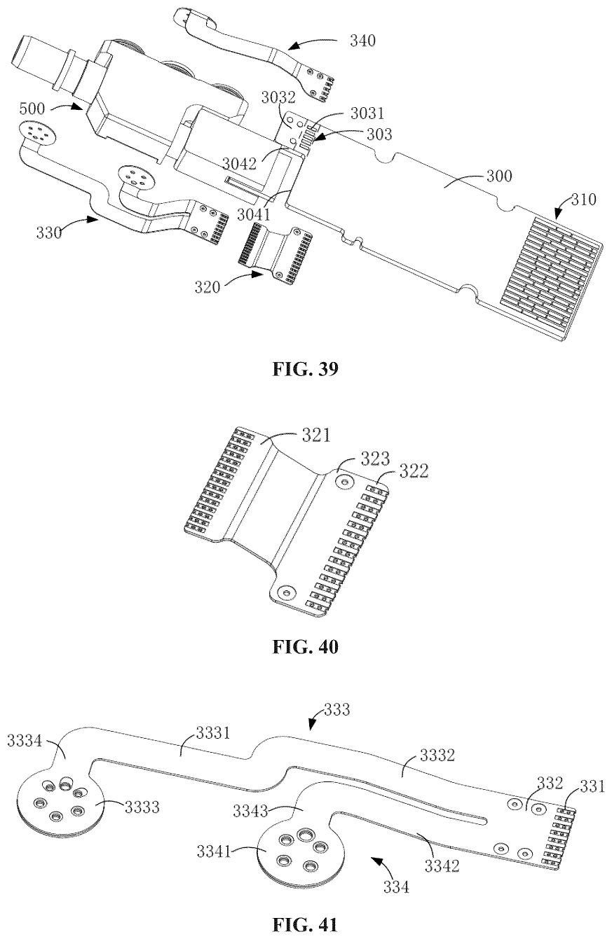

FIG. 38 is a first exploded schematic diagram illustrating an internal structure of an optical module provided according to some embodiments of the present disclosure, and FIG. 39 is a second exploded schematic diagram illustrating an internal structure of an optical module provided according to some embodiments of the present disclosure. As shown in FIGS. 38 and 39, the optical module further includes a first flexible circuit board 320, a second flexible circuit board 330 and a third flexible circuit board 340. One end of the circuit board 300 that is away from the golden finger 310 is provided with a first electrical connection area 301, a second electrical connection area 302 and a third electrical connection area 303. One end of the first flexible circuit board 320 is connected to the first circuit board 430, and the other end of the first flexible circuit board 320 is connected to the first electrical connection area 301. One end of the second flexible circuit board 330 is connected to the first light reception component 530 and the third light reception component 550, respectively, and the other end of the second flexible circuit board 330 is connected to the second electrical connection area 302. One end of the third flexible circuit board 340 is connected to the second light reception component 540, and the other end of the third flexible circuit board 340 is connected to the third electrical connection area 303.

In some embodiments, the end of the circuit board 300 that is away from the golden finger 310 is formed with a cut-off corner 304, which causes one side of the end of the circuit board 300 to be longer and the other side thereof to be shorter (that is, it makes the end of the circuit have a longer side and a shorter side). One end of the first circuit board 430 is located in the cut-off corner 304 in such a way that the longer side of the end of the circuit board 300 extends along one side of the first circuit board 430, and the shorter side of the end of the circuit board 300 extends to the one end of the first circuit board 430. In this way, it not only facilitates the circuit board 300 to fully utilize the internal space of the shell, but also enables the circuit board 300 to adapt to the optical accommodation component 500 and the light emission component 400. For example, the cut-off corner 304 includes a first end face 3041 extends along a width direction of the circuit board 300 and a second end face 3042 extends along a length direction of the circuit board 300. With the first end face 3041 and the second end face 3042, an L-shaped cut-off corner is formed at one end of the circuit board 300. The first end face 3041 is located at one end of the first circuit board 430, and the second end face 3042 is located at one side of first circuit board 430.

In some embodiments, the first electrical connection area 301 is provided on a top surface of the shorter side of the end of the circuit board that is away from the golden finger, the second electrical connection area 302 is provided on a top surface of the longer side of the end of the circuit board that is away from the golden finger, and the third electrical connection area 303 is provided on a bottom surface of the longer side. The first electrical connection area 301, the second electrical connection area 302 and the third electrical connection area 303 are located at edge portions of the surface of the circuit board 300, such that the first electrical connection area 301, the second electrical connection area 302 and the third electrical connection area 303 are as close as possible to the optical accommodation component 500 and the light emission component 400, which facilitates to effectively control the area occupied by the connection of the circuit board 300 with the first flexible circuit board 320, the second flexible circuit board 330 and the third flexible circuit board 340. For example, the third electrical connection area 303 is located opposite to the second electrical connection area 302, which may help to reduce crosstalk of signals transmitted in the second flexible circuit board 330 and the third flexible circuit board 340.

In some embodiments, the first electrical connection area 301 includes a first pad group 3011, with which the first flexible circuit board 320 is connected through welding; the second electrical connection area 302 includes a second pad group 3021, with which the second flexible circuit board 330 is connected through welding; the third electrical connection area 303 includes a third pad group 3031, with which the third flexible circuit board 340 is connected through welding. For example, the first pad group 3011, the second pad group 3021, and the third pad group 3031 each include a plurality of pads.

In some embodiments, the first electrical connection area 301 further includes a first support portion 3012, which is located at one side of the first pad group 3011 and near the end of the first circuit board 430. The first support portion 3012 supports and connects with the other end of the first flexible circuit board 320. The second electrical connection area 302 further includes a second support portion 3022, which is located at one side of the second pad group 3021 and near the light reception component. The second support portion 3022 supports and connects with the other end of the second flexible circuit board 330. The third electrical connection area 303 further includes a third support portion 3032, which is located at one side of the third pad group 3031 and near the reception component. The third support portion 3032 supports and connects with the other end of the third flexible circuit board 340.

FIG. 40 is a structural schematic diagram of a first flexible circuit board provided according to some embodiments of the present disclosure. As shown in FIG. 40, one end of the first flexible circuit board 320 is provided with a first welding portion 321, and the other end of the first flexible circuit board 320 is provided with a second welding portion 322. The first welding portion 321 and the second welding portion 322 each are provided with a plurality of pads. The first welding portion 321 is configured to be welded and connected with the first circuit board 430, and the second welding portion 322 is configured to be welded and connected with the first pad group 3011.

In some embodiments, the first flexible circuit board 320 is further provided thereon with a first support-connection portion 323, with one end of the first support-connection portion 323 connected to the first welding portion 321, and the other end of the first support-connection portion 323 connected to the second welding portion 322. The first support-connection portion 323 is supported on and connected to the first support portion 3012, which facilitates to improve the connection reliability between the first flexible circuit board 320 and the circuit board 300. Since the size of the second welding portion 322 is relatively small, when the second welding portion 322 is welded and connected to the first pad group 3011, the connection strength of the second welding portion 322 and the first pad group 3011 is limited. With the first support portion 3012 supporting and connecting with the first support-connection portion 323, the connection firmness between the first flexible circuit board 320 and the circuit board 300 is improved.

FIG. 41 is a structural schematic diagram of a second flexible circuit board provided according to some embodiments of the present disclosure. As shown in FIG. 41, the second flexible circuit board 330 includes a third welding portion 331 having a plurality of pads. The third welding portion 331 is welded and connected to the second pad group 3021. One end of the third welding portion 331 is provided with a second support-connection portion 332. The second support-connection portion 332 is supported and connected to the second support portion 3022, which improves the connection reliability between the second flexible circuit board 330 and the circuit board 300.

In some embodiments, the second flexible circuit board 330 includes a first branch 333 and a second branch 334; one end of the first branch 333 is configured to electrically connect with the first light reception component 530, and the other end of the first branch 333 is connected with one end of the second support-connection portion 332; one end of the second branch 334 is configured to electrically connect with the third light reception component 550, and the other end of the second branch 334 is connected with one end of the second support-connection portion 332; and the other end of the first branch 333 and the other end of the second branch 334 are arranged side by side. With the first branch 333 and the second branch 334 being provided at one end of the second flexible circuit board 330, the one end of the second flexible circuit board 330 configured to electrically connect with the first light reception component 530 and with the third light reception component 550 is divided into two separated branches, while the other end of the second flexible circuit board 330, which is configured to electrically connect with the circuit board 300, is complete. In this way, it not only facilitates electrical connections between the second flexible circuit board 330 and the first light reception component 530 as well as between the second flexible circuit board 330 and the third light reception component 550, but also facilitates the electrical connection between the second flexible circuit board 330 and the circuit board 300.

In some embodiments, the first branch 333 includes a first extension 3331, a second extension 3332 and a fourth welding portion 3333. A side edge of the fourth welding portion 3333 is connected to a side edge of one end of the first extension 3331. The fourth welding portion 3333 is configured to be welded and connected with the first light reception component 530. A side edge of the other end of the first extension 3331 is connected to a side edge of one end of the second extension 3332, and the other end of the second extension 3332 is connected to the second support-connection portion 332. A length extension direction of the first extension 3331 is not in the same straight line as a length extension direction of the second extension 3332. The bending configuration of one end of the first branch 333 from the fourth welding portion 3333 to the second extension 3332 makes the fourth welding portion 3333 located at one side of the first extension 3331 while the second extension 3332 located at the other side of the first extension 3331.

In some embodiments, the first branch 333 further includes a first bending portion 3334, one end of which is connected to the side edge of the fourth welding portion 3333, and the other end thereof is connected to the side edge of the one end of the first extension 3331. The first bending portion 3334 is provided to facilitate achieving bending connection of the fourth welding portion 3333 to the first extension 3331.

In some embodiments, the second branch 334 includes a fifth welding portion 3341 and a third extension portion 3342. A side edge of the fifth welding portion 3341 is connected to a side edge of one end of the third extension 3342, such that the fifth welding portion 3341 is located at one side of the third extension 3342; the other end of the third extension 3342 is connected to the second support-connection portion 332; and the fifth welding portion 3341 is configured to be welded and connected to the third light reception component 550.

In some embodiments, the third extension 3342 and the second extension 3332 are arranged side by side, and a length extension direction of the third extension 3342 is on the same straight line as a length extension direction of the first extension 3331.

In some embodiments, the second branch 334 further includes a second bending portion 3343, one end of which is connected to the side edge of the fifth welding portion 3341, and the other end of the second bending portion 3343 is connected to the side edge of the third extension 3342. The second bending portion 3343 is provided to facilitate achieving the bending of the fifth welding portion 3341 to the third extension 3342.

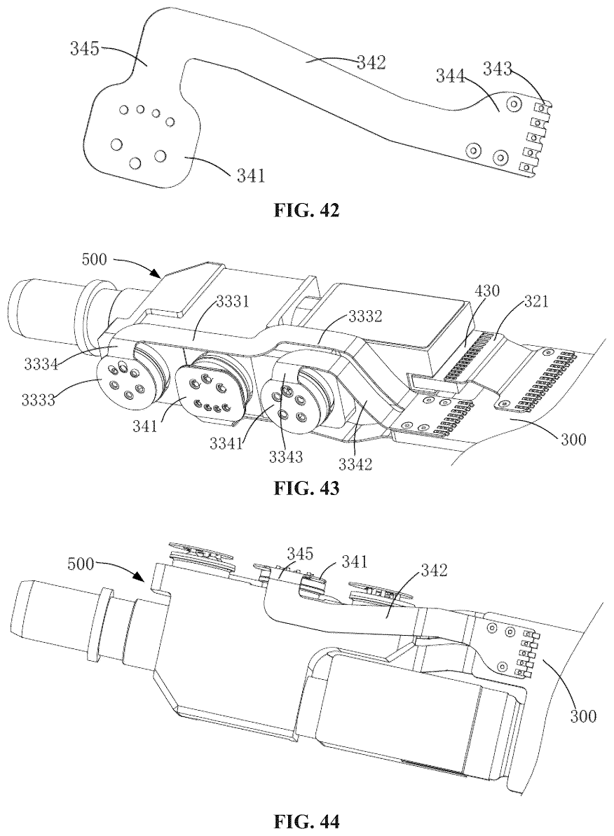

FIG. 42 is a structural schematic diagram of a third flexible circuit board provided according to some embodiments of the present disclosure. As shown in FIG. 42, the third flexible circuit board 340 includes a sixth welding portion 341, a fourth extension 342, and a seventh welding portion 343. A side edge of the sixth welding portion 341 is connected to a side edge of one end of the fourth extension 342, and the other end of the fourth extension 342 is connected to the seventh welding portion 343, such that the sixth welding portion 341 is located at one side of an extension direction of the fourth extension 342. The sixth welding portion 341 is welded and connected to the second light reception component 540. The seventh welding portion 343 includes a plurality of pads, and is welded and connected to the third pad group 3031.

In some embodiments, the third flexible circuit board 340 further includes a third support-connection portion 344, one end of which is connected to the fourth extension 342, and the other end thereof is connected to the seventh welding portion 343. The third support-connection portion 344 is supported and connected to the third support portion 3032, which improves the connection reliability between the third flexible circuit board 340 and the circuit board 300.

In some embodiments, the third flexible circuit board 340 further includes a third bending portion 345, one end of which is connected to the side edge of the sixth welding portion 341, and the other end thereof is connected to the side edge of the one end of the fourth extension 342. The third bending part 345 is provided to facilitate achieving the bending of the sixth welding part 341 to the fourth extension part 342.

FIG. 43 is a first schematic diagram illustrating a partial structure of an optical module provided according to some embodiments of the present disclosure, and FIG. 44 is a second schematic diagram illustrating a partial structure of an optical module provided according to some embodiments of the present disclosure. FIGS. 43 and 44 show connection state diagrams of a light emission component, a light reception component and a circuit board. As shown in FIGS. 43 and 44, the second flexible circuit board 330 extends from one end of the circuit board 300 to a top of the optical accommodation component 500, and then bends from the top of the optical accommodation component 500 to the side of the optical accommodation component 500, such that the second flexible circuit board 330 correspondingly connects with the first light reception component 530 and the third light reception component 550; the third flexible circuit board 340 extends from the one end of the circuit board 300 to a bottom of the optical accommodation component 500, and then bends from the bottom of the optical accommodation component 500 to the side of the optical accommodation component 500, such that the third flexible circuit board 340 connects with the second light reception component 540. A middle portion of the second flexible circuit board 330 is mainly located on the top of the optical accommodation component 500, while a middle portion of the third flexible circuit board 340 is mainly located on the bottom of the optical accommodation component 500. In this way, it not only facilitates reducing signal crosstalk between the second flexible circuit board 330 and the third flexible circuit board 340, but also facilitates effectively controlling widths of the second flexible circuit board 330 and the third flexible circuit board 340, such that the widths of the second flexible circuit board 330 and the third flexible circuit board 340 are within appropriate ranges, facilitating the mounting of the second flexible circuit board 330 and the third flexible circuit board 340 in the optical module.

In some embodiments, the second extension 3332 and the third extension 3342 extend from one end of the circuit board 300 to the top of the first cavity member, respectively; the third extension 3342 is located at an edge portion of the top of the first cavity member, and the first extension 3331 is located at an edge portion of the top of the first cavity member; the second bending portion 3343 is located at an edge portion of the third light reception component 550, and the second bending portion 3343 realizes the bending of the second branch 334 from the top of the first cavity member to the side of the first cavity member; and the first bending portion 3334 is located at an edge portion of the first light reception component 530, and the first bending portion 3334 realizes the bending of the first branch 333 from the top of the first cavity member to the side of the first cavity member.

In some embodiments, the fourth extension 342 extends from one end of the circuit board 300 to the bottom of the first cavity member; the fourth extension 342 is located at an edge portion of the bottom of the optical accommodation component 500, the third bending portion 345 is located at an edge portion of the second light reception component 540, and the third bending portion 345 realizes the bending of the third flexible circuit board 340 from the bottom of the first cavity member to the side of the first cavity member.

In some embodiments, reference grounds are provided on opposite faces of the second flexible circuit board 330 and the third flexible circuit board 340, and the reference grounds can block electromagnetic wave radiation. Therefore, in the case that the second light reception component 540 has the highest receiving rate among the three light reception components, the arrangements of the second flexible circuit board 330 and the third flexible circuit board 340 shown in FIGS. 43 and 44 may more effectively reduce crosstalk during signal transmission, thereby facilitating avoiding impact of electrical signals transmitted through the second flexible circuit board 330 on electrical signals transmitted through the third flexible circuit board 340, and ensuring the quality of electrical signals output from the third light reception component 550.

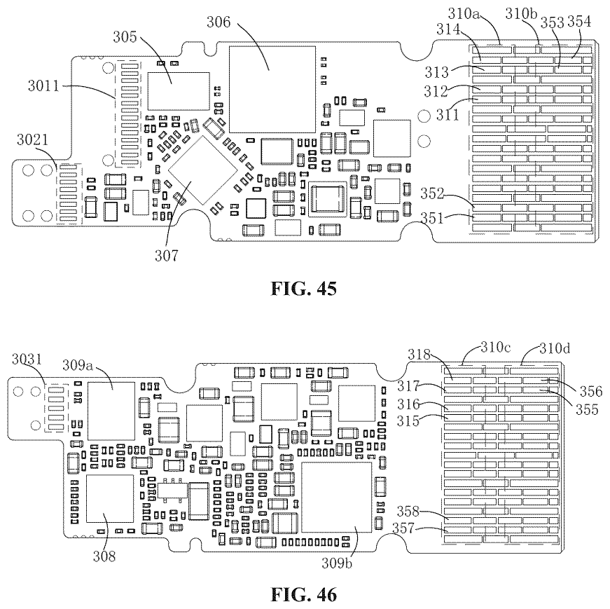

FIG. 45 is a first diagram illustrating a circuit board provided according to some embodiments of the present disclosure in a usage state, and FIG. 46 is a second diagram illustrating a circuit board provided according to some embodiments of the present disclosure in a usage state. FIGS. 45 and 46 illustrate a layout of devices on a circuit board 300.

As shown in FIG. 45, the circuit board 300 is provided, on a first surface thereof, with a first driver 305, which is located beside the first electrical connection area 301, and the first driver 305 is electrically connected to the first laser assembly 451 so as to drive and control the first laser assembly 451 to generate the first-wavelength optical signal. For example, the first driver 305 is provided at one side of the first pad group 3011 that is away from the first support portion 3012, and is electrically connected to the first laser assembly 451 via the first pad group 3011. The first driver 305 is located beside the first pad group 3011 and near the first pad group 3011, in this way, it not only facilitates minimizing transmission line of the high-frequency drive signal from the first driver 305 to the first laser assembly 451, so as to reduce insertion loss of the high-frequency drive signal from the first driver 305 to the first laser assembly 451 and ensure amplitude of the high-frequency drive signal, thereby improving such optical performance as extinction ratio of the first laser assembly 451, but also can effectively reduce the spatial electromagnetic radiation generated by the high-frequency drive signal output from the first driver 305, as well as the exposure to electromagnetic radiation, thereby ensuring the quality of the electrical signal output by the first driver 305.

As shown in FIG. 45, the first surface of the circuit board 300 is further provided with a DSP chip 306, which is located beside the first driver 305 and near the first driver 305, and the DSP chip 306 is electrically connected to the first driver 305. The DSP chip 306 receives a first electrical signal transmitted by the master computer via the golden finger 310, and performs a preprocessing, such as shaping, on the first electrical signal. The preprocessed electrical signal is transmitted to the first driver 305, and the first driver 305 drives the first laser assembly 451 based on the received electrical signal.

As shown in FIG. 45, the first surface of circuit board 300 is further provided with a second driver 307, which is located beside the first driver 305 and beside the first pad group 3011, and the second driver 307 is electrically connected to the third laser assembly 453 such that the third laser assembly 453 is driven by the second driver 307 to generate the third-wavelength optical signal. For example, the second driver 307 is placed on the circuit board 300 in an inclined manner such that one corner of the second driver 307 facing and close to the first driver 305; a first side face and a second side face are included on two sides of the corner, with the first side face inclined towards one end of the circuit board 300 and the second side face inclined towards the other end of the circuit board 300. The first side face of the second driver 307 is close to the first pad group 3011, and the second side face of the second driver 307 is close to the DSP chip 306. The second driver 307 is electrically connected to the third laser assembly 453 via the first pad group 3011.

The DSP chip 306 receives the third electrical signal transmitted by the master computer via the golden finger 310, and performs preprocessing, such as shaping, on the third electrical signal, the preprocessed third electrical signal is transmitted to the second driver 307 through the DSP chip 306, and the second driver 307 drives the third laser assembly 453 based on the received electrical signal; alternatively, the third electrical signal transmitted by the golden finger 310 is directly transmitted to the second driver 307, and the second driver 307 drives the third laser assembly 453 based on the received electrical signal. With the inclined arrangement of the second driver 307 and on the basis of adapting to the first driver 305, it is convenient to coordinate a circuit wiring length between the second driver 307 and the third laser assembly 453 with a circuit wiring length between the second driver 307 and the DSP chip 306 or golden finger 310, and it facilitates controlling transmission line of high-frequency electrical signal from the second driver 307 to the third laser assembly 453 to be short, thereby reducing the insertion loss of high-frequency electrical signal from the second driver 307 to the third laser assembly 453.

In some embodiments, the second driver 307 is also electrically connected to the second pad group 3021 to be electrically connected to the first light reception component 530 via the second pad group 3021. The second driver 307 is configured to amplify the fourth electrical signal output by the first light reception component 530 based on the received fourth-wavelength optical signal, and transmit the fourth electrical signal, which has been limiting-amplified, to the golden finger 310. The inclined arrangement of the second driver 307 facilitates coordination of the circuit wiring length between the second driver 307 and the first light reception component 530 with the circuit wiring length between the second driver 307 and the golden finger 310, to ensure the quality of the fourth electrical signal. In some embodiments, the first surface of the circuit board 300 is provided with a first column of gold fingers 310a and a second column of gold fingers 310b. The first column of gold fingers 310a and the second column of gold fingers 310b each include a plurality of pins, and the second column of gold fingers 310b is closer to the edge of the circuit board 300 than the first column of gold fingers 310a. A second surface of the circuit board 300 is provided with a third column of gold fingers 310c and a fourth column of gold fingers 310d, and the third column of gold fingers 310c and the fourth column of gold fingers 310d each include a plurality of pins, and the fourth column of gold fingers 310d is closer to the edge of the circuit board 300 than the third column of gold fingers 310c.

In some embodiments, the first column of gold fingers 310a includes a 33rd pin 311, a 34th pin 312, a 36th pin 313, and a 37th pin 314, with the 33rd pin 311, the 34th pin 312, the 36th pin 313 and the 37th pin 314 located near the DSP chip 306; the 33rd pin 311, the 34th pin 312, the 36th pin 313 and 37th pin 314 are respectively electrically connected to the DSP chip 306. For example, a plurality of high-frequency transmission lines are arranged on the first surface of circuit board 300, and the 33rd pin 311, the 34th pin 312, the 36th pin 313 and the 37th pin 314 are respectively electrically connected to the DSP chip 306 via a corresponding high-frequency transmission line, The high-frequency transmission lines do not pass through an inner layer of the circuit board 300. The high-frequency transmission lines electrically connecting the DSP chip 306 with the 33rd pin 311, the 34th pin 312, the 36th pin 313 and the 37th pin 314 only run on the surface of the circuit board 300, thereby ensuring impedance continuity of electrical connection lines from the 33rd pin 311, the 34th pin 312, the 36th pin 313 and the 37th pin 314 to the DSP chip 306, minimizing the transmission line of the first electrical signal and reducing transmission loss of the first electrical signal, and ensuring the transmission quality of the first electrical signal.

In some embodiments, the master computer sends the first electrical signal to the DSP chip 306 in a form of NRZ type electrical signal or PAM4 type electrical signal through the 33rd pin 311, the 34th pin 312, the 36th pin 313 and the 37th pin 314. For example, in the case that the first laser assembly 451 emits the first-wavelength optical signal in an emission rate of 50G, when the master computer adopts a data transmission way of 2×25G NRZ, the 36th pin 313 and 37th pin 314 form a transmission channel I, the 33rd pin 311 and 34th pin 312 form a transmission channel II, the transmission channel I transmits one path of 25G NRZ type electrical signal, the transmission channel II transmits one path of 25G NRZ type electrical signal, and the DSP chip 306 combines the two paths of 25G NRZ type electrical signals into one path of 50G NRZ type electrical signal and transmits it to the first driver 305; and when the master computer adopts a data transmission manner of 1×25G PAM4, the 36th pin 313 and 37th pin 314 are used to transmit one path of 25G PAM4 type electrical signal, and the DSP chip 306 converts the one path of 25G PAM4 type electrical signal into one path of 50G NRZ type electrical signal and transmits it to the first driver 305.

As shown in FIG. 46, a second surface of the circuit board 300 is provided with a third driver 308, which is located opposite to the first electrical connection area 301, and is electrically connected to the second laser assembly 452 to drive and control the second laser assembly 452 by the second laser assembly 452 to generate the second-wavelength optical signal. For example, the third driver 308 is electrically connected to the second laser assembly 452 via the first pad group 3011. The third driver 308 and the first electrical connection area 301 are arranged back to back, which facilitates minimizing transmission line of high-frequency electrical signal from the third driver 308 to the second laser assembly 452, thereby reducing insertion loss of the high-frequency electrical signal from the third driver 308 to the second laser assembly 452.

In some embodiments, the third driver 308 is also electrically connected to the second pad group 3021 to electrically connect the third light reception component 550 via the second pad group 3021. The third driver 308 is configured to amplify the sixth electrical signal output by the third light reception component 550 based on a received sixth-wavelength optical signal, and transmit a limiting-amplified sixth electrical signal to the golden finger 310.

In some embodiments, since the third driver 308 and the first driver 305 are main heat generating components in the optical module, with an arrangement in which a projection of the third driver 308 on the circuit board 300 does not intersect with a projection of the first driver 305 on the circuit board 300, thermal crosstalk between the third driver 308 and the first driver 305 may be effectively reduced.

As shown in FIG. 46, the second surface of the circuit board 300 is further provided with a LIA 309a, which is located beside the third electrical connection area 303, and is electrically connected to the second light reception component 540, such that the LIA 309a limiting-amplifies the fifth electrical signal output by the second light reception component 540 based on a received fifth-wavelength optical signal and transmits a limiting-amplified fifth electrical signal to the golden finger 310. For example, the LIA 309a is located at a side of the third pad group 3031 that is away from the third support portion 3032, and the LIA 309a is electrically connected to the second light reception component 540 via the third pad group 3031. The LIA 309a is disposed beside the third pad group 3031 to minimize transmission line of the fifth electrical signal from the LIA309a to the second light reception component 540. The fifth electrical signal output by the second light reception component 540 is a small signal which is sensitive to impedance matching and signal insertion loss in the transmission line. Therefore, by controlling the transmission line from the LIA 309a to the second light reception component 540 to be the shortest, it may ensure the transmission quality of the fifth electrical signal.

In some embodiments, an electrical connection line between the LIA 309a and the third pad group 3031 is located on a bottom of the circuit board 300, that is, the electrical connection line between the LIA 309a and the third pad group 3031 does not run through the inner layer of the circuit board 300, which ensures impedance continuity of the electrical connection line between the LIA 309a and the third pad group 3031, minimizes the transmission line of the fifth electrical signal, and reduces the transmission loss of the fifth electrical signal, thereby ensuring the quality of the fifth electrical signal.

In some embodiments, the second surface of the circuit board 300 is further provided with a MCU 309b, and the MCU 309b and the DSP chip 306 are main heat generating components in the optical module. With an arrangement in which a projection of the MCU 309b on the circuit board 300 does not intersect with a projection of the DSP chip 306 on circuit board 300, thermal crosstalk between the MCU 309b and the DSP chip 306 may be effectively reduced.

In some embodiments, the third column of gold fingers 310c includes the 14th pin 315, the 15th pin 316, the 17th pin 317 and the 18th pin 318, with the 14th pin 315, the 15th pin 316, the 17th pin 317 and the 18th pin 318 located near the LIA 309a. The 14th pin 315, 15th pin 316, 17th pin 317 and 18th pin 318 are respectively electrically connected to the LIA 309a. The fifth electrical signal limiting-amplified by the LIA 309a is transmitted to the 14th pin 315, 15th pin 316, 17th pin 317 and 18th pin 318 so as to be transmitted to the master computer via the 14th pin 315, 15th pin 316, 17th pin 317 and 18th pin 318.

In the embodiments of the present disclosure, the 14th pin 315, 15th pin 316, 17th pin 317, and 18th pin 318 located near the LIA 309a in the golden finger 310 are defined to transmit the limiting-amplified fifth electrical signal, so as to minimize the transmission line of the limiting-amplified fifth electrical signal, ensure the impedance continuity on the transmission line, reduce transmission loss of the fifth electrical signal, and ensure the transmission quality of the fifth electrical signal.

In some embodiments, the second light reception component 540 receives the optical signal at a transmission rate of 25G or 50G. For example, in the case that the second light reception component 540 outputs the fifth electrical signal at a rate of 50G, when the fifth electrical signal is a 2×25G NRZ type electrical signal, the 14th pin 315 and the 15th pin 316 form a receiving channel I, the 17th pin 317 and the 18th pin 318 form a receiving channel II, the receiving channel I transmits one path of 25G NRZ type electrical signal, and the receiving channel II transmits one path of 25G NRZ type electrical signal; when the fifth electrical signal is a 1×25G PAM4 type electrical signal, the 17th pin 317 and 18th pin 318 transmit one path of 25G PAM4 type electrical signal; and when the fifth electrical signal is a 1×50G NRZ type electrical signal, the 17th pin 317 and the 18th pin 318 transmit one path of 50G NRZ type electrical signal.

In some embodiments, the second column of gold fingers 310b includes a 74th pin 353 and a 75th pin 354, which are electrically connected to the third driver 308 or the DSP chip 306. For example, the 74th pin 353 and the 75th pin 354 are electrically connected to the third driver 308, the master computer transmits the second electrical signal through the 74th pin 353 and the 75th pin 354 to the third driver 308, and the third driver 308 drives the second laser assembly 452 based on the received second electrical signal.

In some embodiments, the first column of gold fingers 310a further includes a 21st pin 351 and a 22nd pin 352, which are electrically connected to the second driver 307. For example, the second driver 307 transmits the amplified fourth electrical signal to the 21st pin 351 and the 22nd pin 352 so as to transmit it to the master computer via the 21st pin 351 and the 22nd pin 352.

In some embodiments, the third column gold finger 310c further includes a 2nd pin 357 and a 3rd pin 358, which are electrically connected to the second driver 307 or the DSP chip 306. For example, the 2nd pin 357 and the 3rd pin 358 are electrically connected to the second driver 307, the master computer transmits the third electrical signal to the second driver 307 via the 2nd pin 357 and the 3rd pin 358, and the second driver 307 drives the third laser assembly 453 based on the received third electrical signal.

In some embodiments, the fourth column gold finger 310d includes a 55th pin and a 56th pin that are electrically connected to the third driver 308. For example, the third driver 308 transmits the amplified sixth electrical signal to the 55th pin 355 and 56th pin 356 so as to transmit it to the master computer via the 55th pin 355 and 56th pin 356.

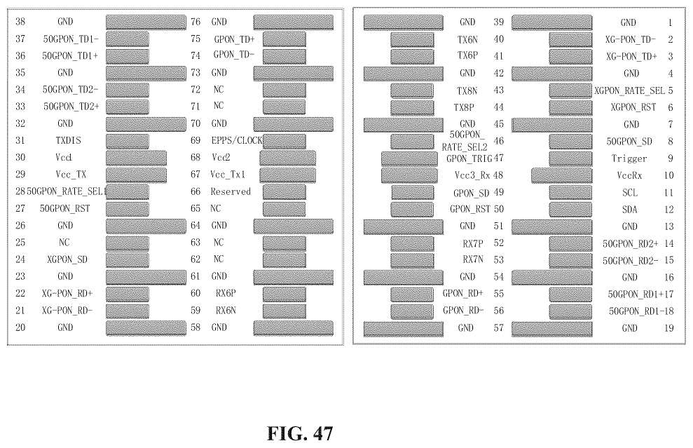

FIG. 47 is a diagram illustrating a pin definition of a gold finger provided according to some embodiments of the present disclosure. FIG. 47 shows a usage definition of the gold finger. As shown in FIG. 47, the gold finger 310 includes 76 pins, which support hot swapping. The 76 pins are evenly divided into four columns, in which: the first column of gold fingers includes the 20th pin to the 38th pin, and the second column of gold fingers includes the 58th pin to the 76th pin, and the first and second columns of gold fingers are located on the first surface of the circuit board 300; and the third column of gold fingers includes the 1st pin to the 19th pin, and the fourth column of gold fingers includes the 39th pin to the 57th pin, and the third and fourth columns of gold fingers are located on the second surface of the circuit board 300.

For example, the first laser assembly 451 has a transmission rate of 50G, the second laser assembly 452 has a transmission rate of 2.5G, the third laser assembly 453 has a transmission rate of 10G; the photodetector in the first light reception component 530 has a reception rate of 10G, the photodetector in the second light reception component 540 has a reception rate of 50G, the photodetector in the third light reception component 550 has a reception rate of 2.5G, and the definition of the pins in the golden finger 310 is shown in FIG. 47.

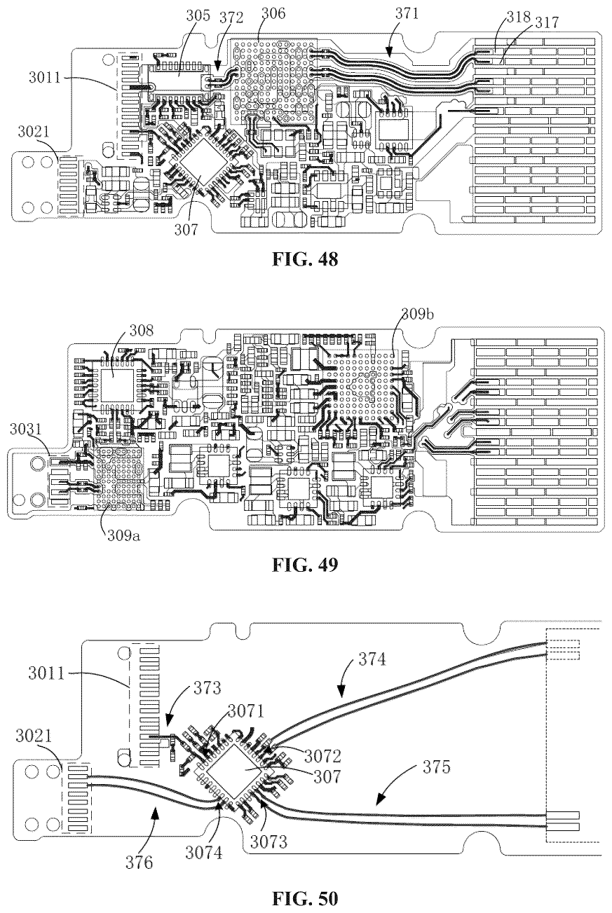

FIG. 48 is a third diagram illustrating a circuit board provided according to some embodiments of the present disclosure in a usage state, and FIG. 49 is a fourth diagram illustrating a circuit board provided according to some embodiments of the present disclosure in a usage state. FIGS. 48 and 49 illustrate a wiring layout on the circuit board 300 and a connection status between devices and the circuit board 300. As shown in FIGS. 48 and 49, the first driver 305 is electrically connected to the circuit board 300 via pins, the DSP chip 306 is connected to the circuit board 300 via solder balls, the second driver 307 is connected to the circuit board 300 via pads, the third driver 308 is electrically connected to the circuit board 300 via pins, the LIA 309a is electrically connected to the circuit board via solder balls, and the MCU 309b is connected to the circuit board 300 via solder balls.

The first surface of the circuit board 300 is provided with a first high-frequency transmission line group 371 and a second high-frequency transmission line group 372. One end of the first high-frequency transmission line group 371 is electrically connected to the DSP chip 306, and the other end of the first high-frequency transmission line group 371 is electrically connected to the golden finger 310. One end of the second high-frequency transmission line group 372 is electrically connected to the first driver 305, and the other end of the second high-frequency transmission line group 372 is electrically connected to the DSP chip 306. The first high-frequency transmission line group 371 and the second high-frequency transmission line group 372 each include a plurality of high-frequency transmission lines. For example, the first high-frequency transmission line group 371 includes four high-frequency transmission lines, and the second high-frequency transmission line group 372 includes two high-frequency transmission lines. The high-frequency transmission lines electrically connecting the first driver 305 with the pads of the first pad group 3011 are located on the first surface of the circuit board, which facilitates reducing electrical loss of the high-frequency drive signal output by the first driver 305. The high-frequency transmission lines electrically connecting the second driver 307 with the pads of the first pad group 3011 are located on the first surface of the circuit board, which facilitates reducing electrical loss of the high-frequency drive signal output by the second driver 307. The high-frequency transmission lines electrically connecting the LIA 309a with the pads of the third pad group 3031 are located on the second surface of the circuit board, which facilitates reducing electrical loss of the electrical signal output by the second light reception component 540 from the third pad group 303 to the LIA 309a.

FIG. 50 is a high-frequency signal transmission circuit structure of a second driver provided according to some embodiments of the present disclosure. As shown in FIG. 50, the second driver 307 includes a first side face 3071, a second side face 3072, a third side face 3073, and a fourth side face 3074. The first side face 3071, the second side face 3072, the third side face 3073 and the fourth side face 3074 are sequentially connected to form side faces of the second driver. The first side face 3071 faces the first pad group 3011 in an inclined manner, the second side face 3072 and the third side face 3073 each face the golden finger 310 in an inclined manner, and the second side face 3072 also faces the DSP chip 306 in an inclined manner; and the fourth side face 3074 faces the second pad group 3021 in an inclined manner. In this way, on the basis of adapting to the first driver 305, the high-frequency signal transmission line between the second driver 307 and the first pad group 3011 may be controlled to be short, and the high-frequency signal transmission line between the second driver 307 and the second pad group 3021 may also be controlled to be short, to facilitate coordinating lengths of high-frequency signal transmission lines between the second driver 307 and the first pad group 3011 as well as between the second driver 307 and the second pad group 3021.

The first side face 3071 is provided with a first output pin, the second side face 3072 is provided with a first input pin, the third side face 3073 is provided with a second output pin, and the fourth side face 3074 is provided with a second input pin. The first output pin 3075 is electrically connected to the first pad group 3011 via a third high-frequency transmission line group 373, the first input pin 3076 is electrically connected to the gold finger 310 via a fourth high-frequency transmission line group 374, the second output pin 3077 is electrically connected to the gold finger 310 via a fifth high-frequency transmission line group 375, and the second input pin 3078 is electrically connected to the second pad group 3021 via a sixth high-frequency transmission line group 376. For example, the third high-frequency transmission line group 373 is located on the first surface of the circuit board 300, while the fourth high-frequency transmission line group 374, the fifth high-frequency transmission line group 375 and the sixth high-frequency transmission line group 376 are located on the same inner layer or different inner layers of the circuit board 300. The first output pin 3075, the first input pin 3076, the second output pin 3077 and the second input pin 3078 each include at least one pin.

The third high-frequency transmission line group 373 is provided to transmit the drive signal to the third laser assembly 451, the fourth high-frequency transmission line group 374 is provided to transmit the third electrical signal to the second driver 307, the sixth high-frequency transmission line group 376 is provided to transmit the fourth electrical signal to the second driver 307, and the fifth high-frequency transmission line group 375 is provided to transmit the limiting-amplified fourth electrical signal.

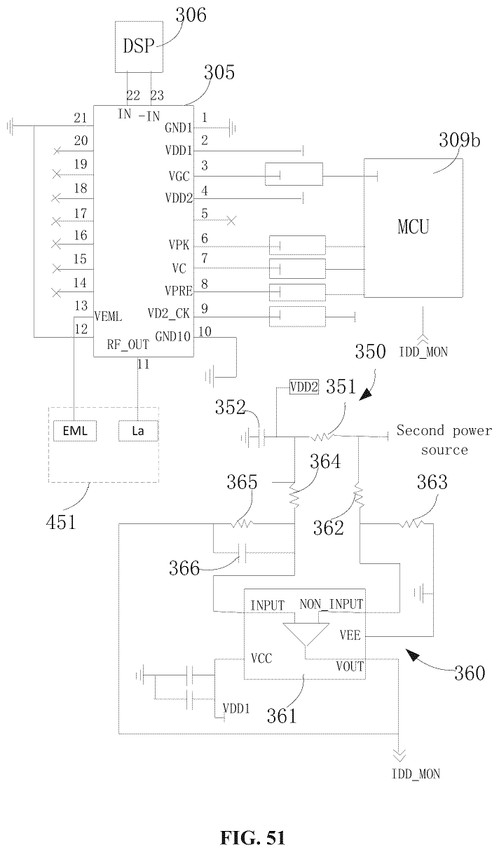

FIG. 51 is a schematic circuit diagram provided according to some embodiments of the present disclosure. As shown in FIG. 51, the first driver 305 includes 23 pins, with a first pin GND1 grounded, a second pin VDD1 connected to a first power supply, a third pin VGC connected to the MCU 309b, a fourth pin VDD2 connected to a second power supply, a sixth pin VPK connected to the MCU 309b, a seventh pin VC connected to the MCU 309b, an eighth pin VPRE connected to a MCU, a ninth pin VD2-0CK connected to the second power supply, a tenth pin GND10 grounded, an eleventh pin RF-OUT and a thirteenth pin VEML are connected to the first laser assembly 451, respectively, a 22nd pin IN and a 23rd pin IN are connected to the DSP chip 306, respectively.

The first driver 305 receives a preprocessed first electrical signal from the DSP chip 306 via the 22nd pin IN and the 23rd pin IN, and outputs a drive signal through the 11th pin RF-OUT and the 13th pin VEML based on the preprocessed first electrical signal so as to drive the first laser assembly 451 to emit the first-wavelength optical signal.

During the operation of the first driver 305, magnitude difference of the first electrical signals input to the first driver 305, working environment temperature of the first driver 305, and the like, will affect indicators of the drive signal output by the first driver 305, causing instability in the drive signal output by the first driver 305 and causing fluctuations in the extinction ratio and other parameters of the first-wavelength optical signal generated by the first laser assembly 451. In the embodiment of the present disclosure, voltage feedback from the 6th pin VPK to the first driver 305 may reflect amplitude change of the drive signal output by the first driver 305. The MCU 309b monitors the amplitude change of the drive signal by monitoring the voltage feedback from the 6th pin VPK. Then, the MCU 309b compensates for the amplitude change of the drive signal output by the first driver 305 by adjusting the voltage applied to the 3rd pin VGC, to stabilize the voltage feedback from the 6th pin VPK at a target value, thereby stabilizing the amplitude of the drive signal output by the first driver 305 within a target range, for example, stabilizing the amplitude of the drive signal at an optimal value.

Parasitic parameters of the first driver 305 may be affected by the working environment, which causes a change in the current of the second power supply for driving the first driver 305, and thus causes the drive signal output by the first driver 305 to be unstable. In the embodiment of the present disclosure, the MCU 309b monitors the current for driving the first driver 305, and by adjusting an output of MCU 309b to the 7th pin VC, stabilizes the current for driving the first driver 305 within a corresponding target range.

In some embodiments, a sampling circuit 350 is provided between the second power supply and the fourth pin VDD2, and the sampling circuit 350 is also connected to the MCU 309b. The MCU 309b connects with the sampling circuit 350, such that the MCU 309b can detect changes in the current of the second power supply for driving the first driver 305 by means of the sampling circuit 350. For example, the sampling circuit 350 includes a sampling resistor 351, which is provided in series between the second power supply and the fourth pin VDD2. The MCU 309b monitors changes in the voltage at both ends of the sampling resistor 351 to detect the changes in the current of the second power supply for driving the first driver 305. The sampling resistor 351 is a resistor having a relatively small resistance, for example, the resistance of the sampling resistor 351 is 0.5Ω.

In some embodiments, the MCU 309b obtains the changes in the current of the second power source for driving the first driver 305, and the MCU 309b adjusts the voltage applied to the 7th pin VC, and, with a closed-loop control, the sampling voltage obtained through the sampling circuit 350 is maintained within the corresponding target range, which in turn maintains the current of the second power source for driving the first driver 305 within the corresponding target range, ensures that the first electrical signal output by the first driver 305 can provide stable output to the first laser assembly 451 under input conditions of different temperature and different signal magnitudes, thereby ensuring the stability of the extinction ratio and other parameters of the first laser assembly 451.

In some embodiments, the sampling circuit 350 further includes a first parallel capacitor 352, one end of which is connected to the 4th pin VDD2, and the other end thereof is grounded. The first parallel capacitor 352 is configured to suppress low-frequency signal interference on the 4th pin VDD2. For example, the first parallel capacitor 352 is a capacitor having a relatively large capacitance value, for example, the capacitance value of the first parallel capacitor 352 is 1 μF. In some embodiments, the first parallel capacitor 352 has a capacitance value greater than 1 μF, so as to ensure the effectiveness of the first parallel capacitor 352 in suppressing low-frequency noise.

In some embodiments, a signal amplification circuit 360 is provided between the sampling circuit 350 and the MCU 309b, and the signal amplification circuit 360 is provided in series between the sampling circuit 350 and the MCU 309b. The signal amplification circuit 360 is configured to amplify the sampling voltage input to the MCU 309b. For example, the signal amplification circuit 360 includes an operational amplifier 361, a first resistor 362, a second resistor 363, a third resistor 364 and a fourth resistor 365. One end of the first resistor 362 is connected to one end of the sampling resistor 351, and the other end of the first resistor 362 is connected to an inverting end of the operational amplifier 361. One end of the second resistor 363 is connected between the other end of the first resistor 362 and the inverting end of the operational amplifier 361, and one end of the second resistor 363 is grounded. One end of the third resistor 364 is connected to the other end of the first resistor 362, and the other end of the third resistor 364 is connected to the non-inverting end of the operational amplifier 361. One end of the fourth resistor 365 is connected between the other end of the third resistor 364 and the non-inverting end of the operational amplifier 361, and the other end thereof is connected to the output end of the operational amplifier 361. The output end of the operational amplifier 361 is connected to the MCU 309b. In some embodiments, the resistance value of the first resistor 362 is equal to the resistance value of the third resistor 364, and the resistance value of the second resistor 363 is equal to the resistance value of the fourth resistor 365, such that the circuit parameters at the two input ends of the operational amplifier 361 are consistent.

In some embodiments, the signal amplification circuit 360 further includes a second parallel capacitor 366, which is connected in parallel with the fourth resistor 365, and is provided to suppress low-frequency signal interference. For example, the second parallel capacitor 366 has a capacitance value in a range of 0.004 μF to 0.04 μF.

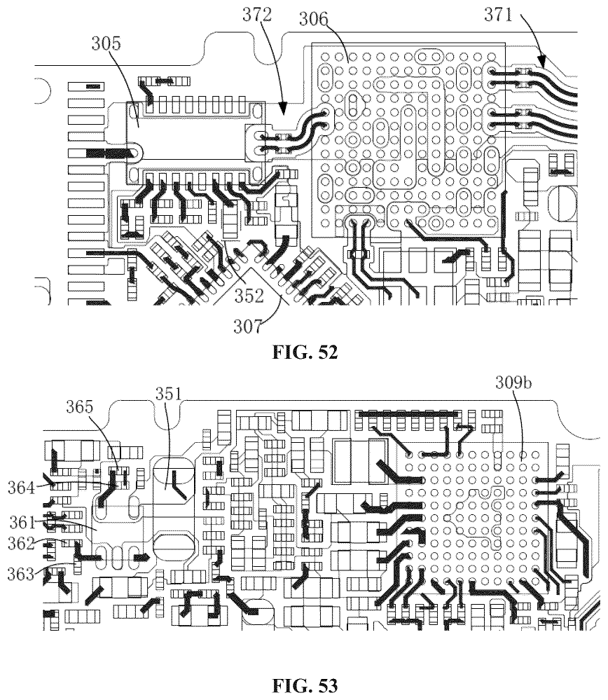

FIG. 52 is a first partial structural schematic diagram of a circuit board provided according to some embodiments of the present disclosure, and FIG. 53 is a second partial structural schematic diagram of a circuit board provided according to some embodiments of the present disclosure. FIGS. 52 and 53 show a device layout on the circuit board. As shown in FIG. 52, the circuit board 300 is provided, on the first surface thereof, with the first parallel capacitor 352, which is located beside the first driver 305 and beside the 4th pin VDD2, with the 4th pin VDD2 electrically connected to the first parallel capacitor 352.

As shown in FIG. 53, the circuit board 300 is provided, on the second surface thereof, with the sampling resistor 351, the signal amplification circuit 360 and the like, which are located at the back of the first driver 305. The 4th pin VDD2 is connected to the sampling resistor 351 through a via hole so as to minimize the connection distance between the sampling resistor 351 and the first driver 305. For example, the sampling resistor 351 is located beside a projection of the first driver 305 toward the second surface of the circuit board 300, the signal amplification circuit 360 is located at a side of the sampling resistor 351 near the third driver 308; and the first resistor 362, the second resistor 363, the third resistor 364 and the fourth resistor 365 are located beside the signal amplification circuit 360. In some embodiments, the first resistor 362 and the second resistor 363 are located between the third driver 308 and the signal amplification circuit 360, and the third resistor 364 and the fourth resistor 365 are located between the signal amplification circuit 360 and a side edge of the circuit board 300.

Finally, it should be noted that the foregoing embodiments are merely intended to describe the technical solutions of the present disclosure, and shall not be construed as limitations thereto. Although the present disclosure is described in detail with reference to the foregoing embodiments, one of ordinary skills in the art should understand that modifications may be made to the technical solutions disclosed in the foregoing embodiments, or equivalent replacements may be made to some of the technical features. However, these modifications or equivalent replacements do not deviate the nature of corresponding technique solution from the spirit and scope of the technical solutions of the embodiments of the present disclosure.

The above only describes some specific embodiments of this disclosure, but the protection scope of this disclosure is not limited thereto. Any changes or replacements envisaged by any person skilled in the art within the scope of the disclosed technology shall fall within the protection scope of this disclosure. Therefore, the protection scope of this disclosure shall be based on those defined by the claims.

What is claimed is:

1. An optical module, comprising:
an optical fiber adapter, one end of the optical fiber adapter being configured to connect with an external optical fiber;
a light emission component configured to output emission optical signals comprising a first-wavelength optical signal, a second-wavelength optical signal and a third-wavelength optical signal; and
an optical accommodation component connected to the other end of the optical fiber adapter so as to receive reception optical signals comprising a fourth-wavelength optical signal, a fifth-wavelength optical signal and a sixth-wavelength optical signal via the optical fiber adapter;
wherein the optical accommodation component comprises:
a first cavity member, one end of the first cavity member being connected to the optical fiber adapter, another end of the first cavity member being connected to the light emission component, and one side of the first cavity member being provided with a first light reception component, a second light reception component and a third light reception component at intervals; and
an optical assembly arranged within the first cavity member and comprising:
a first displacement prism, the first displacement prism having a first reflective surface located in an optical path of the optical fiber adapter;
a first filter located in an optical path of the light emission component and in a reflective optical path of a second reflective surface of the first displacement prism, wherein the emission optical signals are transmitted to the first displacement prism through the first filter, and then transmitted to the optical fiber adapter via the second reflective surface and the first reflective surface of the first displacement prism, and the optical fiber adapter is configured to transmit the reception optical signals to the first filter via the first reflective surface and the second reflective surface of the first displacement prism;
a reflector located in a reflective optical path of the first filter to receive the reception optical signals reflected by the first filter; and
a first wavelength division multiplexer located in a reflective optical path of the reflector and configured to split the reception optical signals reflected by the reflector into the fourth-wavelength optical signal, the fifth-wavelength optical signal and the sixth-wavelength optical signal according to wavelength;
wherein the first light reception component, the second light reception component and the third light reception component are all located in an output optical path of the first wavelength division multiplexer, and the first light reception component is configured to receive the fourth-wavelength optical signal, the second light reception component is configured to receive the fifth-wavelength optical signal, and the third light reception component is configured to receive the sixth-wavelength optical signal.

2. The optical module according to claim 1, wherein the optical assembly further comprises a second displacement prism and a third displacement prism, and wherein
a first reflective surface of the second displacement prism is located in a first output optical path of the first wavelength division multiplexer, and a first reflective surface of the third displacement prism is located in a third output optical path of the first wavelength division multiplexer;
the first light reception component is located in a reflective optical path of a second reflective surface of the second displacement prism; the second light reception component is located in a second output optical path of the first wavelength division multiplexer, and the third light reception component is located in a reflective optical path of a second reflective surface of the third displacement prism.

3. The optical module according to claim 2, wherein the one side of the first cavity member is provided with a first connection hole, a second connection hole and a third connection hole, which are respectively connected to an accommodation cavity of the first cavity member, and wherein the optical assembly is located in the accommodation cavity, the first light reception component is connected to the first connection hole, the second light reception component is connected to the second connection hole, and the third light reception component is connected to the third connection hole.

4. The optical module according to claim 3, wherein the first cavity member comprises a first housing and a first upper cover, and wherein the first housing is formed therein with the accommodation cavity, and the first upper cover is covered on and connected to the first housing;
the first housing comprises a first side plate, a second side plate and a third side plate, which surround the accommodation cavity, wherein a fourth connection hole is provided in the first side plate; the first connection hole, the second connection hole and the third connection hole are provided in the second side plate; and a fifth connection hole is provided in the third side plate;
the other end of the optical fiber adapter is connected to the fourth connection hole, the first displacement prism is located at an edge of the fourth connection hole, one end of the light emission component is connected to the fifth connection hole, and the first filter covers the fifth connection hole.

5. The optical module according to claim 4, wherein a first support surface is provided on an inner wall of the third side plate, and the first filter is disposed on the first support surface; and
the fifth connection hole runs through the first support surface, and the first support surface is inclinedly arranged.

6. The optical module according to claim 4, wherein the optical assembly further comprises a lens assembly, the lens assembly comprises a lens bracket and a lens disposed on the lens bracket, and the lens bracket is embedded in the fourth connection hole.

7. The optical module according to claim 6, wherein the lens bracket comprises a bracket fixing portion, a lens fixing portion and a third through hole, and wherein the third through hole runs through the bracket fixing portion and the lens fixing portion in an optical axis direction of the lens, the bracket fixing portion is connected to a side wall of the fourth connection hole, and the lens is disposed on the lens fixing portion;
the fourth connection hole comprises a front hole, a middle hole and a rear hole that are sequentially communicated and have different inner diameters, and the rear hole is communicated with the accommodation cavity of the first housing; the bracket fixing portion is connected to a side wall of the front hole, the lens is located in the middle hole, and the optical axis of the lens is on the same straight line as a central axis of the rear hole.

8. The optical module according to claim 4, wherein the accommodation cavity comprises a first accommodation cavity, a second accommodation cavity and a third accommodation cavity, which are communicated with each other, and the second accommodation cavity and the third accommodation cavity are located at one side of the second side plate; the first displacement prism, the reflector, the first filter, and the first wavelength division multiplexer are located within the first accommodation cavity, the second displacement prism is located within the second accommodation cavity, and the third displacement prism is located within the third accommodation cavity.

9. The optical module according to claim 8, wherein the first housing further comprises a fourth side plate, a fifth side plate and a sixth side plate, and a baffle plate is disposed in the accommodation cavity; the first side plate, the baffle plate, the third side plate, and the fourth side plate enclose the first accommodation cavity; the first side plate, the second side plate and the baffle plate enclose the second accommodation cavity; the second side plate, the fifth side plate and the sixth side plate enclose the third accommodation cavity; the first connection hole is communicated with the second accommodation cavity, and the third connection hole is communicated with the third accommodation cavity.

10. The optical module according to claim 9, wherein a cut-off corner is formed via outer sides of the third and fifth side plates of the first housing, and one end of the light emission component is located in the cut-off corner; and
a protruding structure is formed via inner sides of the second side plate, the fifth side plate and the sixth side plate of the first housing, which defines the third accommodation cavity, and the third connection hole is disposed in one side of the protruding structure.

11. The optical module according to claim 8, wherein a first recessed groove is provided on a bottom of the first accommodation cavity, a reflector bracket is provided in the first recessed groove, and the reflector is supported on and connected to the reflector bracket; the reflector bracket comprises a bracket base and a bracket support portion disposed on top of the bracket base, and a bottom surface of the bracket base is connected to the first recessed groove.

12. The optical module according to claim 8, wherein the optical assembly further comprises a second filter located in the second output optical path of the first wavelength division multiplexer;
a second recessed groove is provided on the bottom of the first accommodation cavity, which is located at junctions between the first accommodation cavity and the second accommodation cavity as well as between the first accommodation cavity and the third accommodation cavity, and the second filter is disposed in the second recessed groove.

13. The optical module according to claim 1, wherein the first light reception component, the second light reception component and the third light reception component are coaxially packaged light reception components, and reception optical axes of the first light reception component, the second light reception component and the third light reception component are parallel to each other.

14. The optical module according to claim 1, wherein the light emission component comprises:
a second cavity member, one end of the second cavity member being connected to the first chamber member; and
a laser assembly located within the second cavity member and comprises a first laser assembly, a second laser assembly and a third laser assembly, wherein the first laser assembly generates the first-wavelength optical signal, the second laser assembly generates the second-wavelength optical signal, and the third laser assembly generates the third-wavelength optical signal; the first laser assembly, the second laser assembly and the third laser assembly have different transmission rates, the first laser assembly comprises a first high-frequency transmission line that extends in a width direction of the second cavity member, and the third laser assembly comprises a second high-frequency transmission line that extends towards the width direction of the second cavity member;
the light emission component further comprises a first circuit board, the optical module further comprises a circuit board, and the circuit board is electrically connected to the laser assembly via the first circuit board;
the first circuit board is embedded in and connected to the second cavity member such that one end of the first circuit board is located in the second cavity member, and the other end of the first circuit board is located outside the second cavity member; the one end of the first circuit board is formed with a plurality of side faces, which correspondingly surround sides of the first laser assembly, the second laser assembly and the third laser assembly, at least one of the side faces is located at an end of the first high-frequency transmission line, and at least another one of the side faces is located at an end of the second high-frequency transmission line.

15. The optical module according to claim 14, wherein the first circuit board comprises a first circuit board body, one end of the first circuit board body is provided with a first extension and a second extension, with a second spacing being provided between the first extension and the second extension;
a side of the first extension that is close to the second spacing is formed with a first side face, a bottom of the second spacing forms a second side face, a side of the second extension that is close to the second spacing is formed with a third side face, a top of the second extension is formed with a fourth side face, a side of the second extension that is away from the second spacing is formed with a fifth side face, the one end of the first circuit board is also formed with a sixth side face connected with the fifth side face.

16. The optical module according to claim 15, wherein three side faces of the first laser assembly are correspondingly close to the first side face, the second side face and the third side face, and the first high-frequency transmission line extends towards the first side face; a first pad is provided on a top surface at an edge of the first side face; and the first laser assembly comprises a first laser chip, one end of the first high-frequency transmission line is connected to the first laser chip via wire bonding, and the other end of the first high-frequency transmission line is connected to the first pad via wire bonding.

17. The optical module according to claim 15, wherein two side faces of the third laser assembly are close to the fifth and sixth side faces, and the second high-frequency transmission line extends towards the fifth side face; a second pad is disposed on a top surface at an edge of the fifth side face; and the third laser assembly comprises a third laser chip, one end of the second high-frequency transmission line is connected to the third laser chip via wire bonding, and the other end of the second high-frequency transmission line is connected to the second pad via wire bonding.

18. The optical module according to claim 15, wherein one side face of the second laser assembly is close to the fourth side face; a transmission rate of the first laser assembly is greater than a transmission rate of the third laser assembly, and the transmission rate of the third laser assembly is greater than that of the second laser assembly;
the light emission component further comprises a TEC and a support plate disposed within the second cavity member, wherein the support plate is located on top of the TEC and comprises a support plate body, one side of the support plate body is provided with a first spacing, with a first boss disposed at one side of the first spacing and a second boss disposed at the other side of the first spacing; the first laser assembly is disposed on the first boss, the second laser assembly is disposed on the support plate body and located at an edge of the first spacing, and the third laser assembly is disposed on the second boss; sides of the first boss are matched and connected to the second spacing, and the second extension is matched and connected to the first spacing.

19. The optical module according to claim 18, wherein the light emission component further comprises a collimating lens and a second wavelength division multiplexer disposed within the second cavity member; and
the collimating lens comprises a first collimating lens, a second collimating lens and a third collimating lens, wherein the first collimating lens is located between the first laser assembly and the second wavelength division multiplexer, the second collimating lens is located between the second laser assembly and the second wavelength division multiplexer, and the third collimating lens is located between the third laser assembly and the second wavelength division multiplexer.

20. The optical module according to claim 1, wherein the light emission component comprises a second cavity member, one end of the second cavity member is provided with a connecting portion, the connecting portion is provided with a second through hole communicated with an inner cavity of the second cavity member, one end of the connecting portion is connected to the first cavity member, and one end of the second through hole is communicated with an inner cavity of the first cavity member;
an installation groove is provided in the connecting portion at the other end of the second through hole, the installation groove is communicated with the second through hole, and a bottom surface of the installation groove is an inclined surface; an optical window is disposed in the installation groove, and a transparent surface of the optical window is connected to the bottom surface of the installation groove such that the optical window is inclinedly arranged in the installation groove.
